(19) United States
(12) Patent Application Publication
(10) Pub. No.: US 2022/0013588 A1
(43) Pub. Date: Jan. 13, 2022

(54) DISPLAY DEVICE

(71) Applicant: Sony Semiconductor Solutions Corporation, Kanagawa (JP)

(72) Inventors: Yusuke Motoyama, Kanagawa (JP); Reo Asaki, Tokyo (JP)

(21) Appl. No.: 17/296,104

(22) PCT Filed: Dec. 25, 2019
(86) PCT No.: PCT/JP2019/050870

§ 371 Date: May 21, 2021

(30) Foreign Application Priority Data
Jan. 8, 2019 (JP) 2019-001112

(51) Int. Cl. H01L 27/32

(52) U.S. Cl. CPC H01L 27/322; H01L 27/3244

(57) ABSTRACT

A display device is formed by arranging, on a base body, light emitting element groups each including first, second and third light emitting elements. Each of the light emitting elements includes a light emitting region and a color filter layer. In adjacent light emitting elements, an angle (θ) formed by the shortest line segment connecting a boundary line of a bottom surface of the color filter layer facing the light emitting region and an end of the light emitting region with a normal line of the base body is the same in the light emitting elements. Alternatively, a distance from an orthogonal projection image of a boundary line of a bottom surface of the color filter layer onto the base body to an orthogonal projection image of an end of the light emitting region onto the base body is the same in the light emitting elements.

### TECHNICAL FIELD

The present disclosure relates to a display device including a plurality of light emitting elements.

### BACKGROUND ART

In recent years, development of a display device (organic EL display) using an organic electroluminescence (EL) element as a light emitting element is progressing. In this display device, for example, an organic layer including at least a light emitting layer and a second electrode (upper electrode, for example, cathode electrode) are formed on a first electrode (lower electrode, for example, anode electrode) formed so as to be isolated for each pixel. In addition, for example, a red light emitting element obtained by combining an organic layer that emits white light or red light and a red color filter layer, a green light emitting element obtained by combining an organic layer that emits white light or green light and a green color filter layer, and a blue light emitting element obtained by combining an organic layer that emits white light or blue light and a blue color filter layer are each disposed as a sub-pixel, and these sub-pixels constitute one pixel. Light from the light emitting layer is emitted to the outside via the second electrode (upper electrode).

In such a display device, color shift and color mixing often occur disadvantageously. In addition, a display device that solves such a disadvantage is known, for example, from Japanese Patent Application Laid-open No. 2013-152853. In the display device disclosed in this Patent Publication, the thickness of each of various layers constituting a light emitting element, the refractive index of each of materials constituting various layers, the width and thickness of a color filter layer, and the like are specified.

### CITATION LIST

### Patent Document

Patent Document 1: Japanese Patent Application Laid-Open No. 2013-152853

### SUMMARY OF THE INVENTION

### Problems to be Solved by the Invention

By the way, in an actual process of manufacturing a light emitting element, a side surface of a color filter layer is usually in a forward taper state or a reverse taper state. However, in the Patent Publication described above, such an inclination of the side surface of the color filter layer is not taken into consideration. Moreover, since the inclination angle (taper angle) of the side surface of the color filter layer is usually different among light emitting elements, improvement of a viewing angle characteristic cannot be expected unless these inclination angles are taken into consideration. In particular, in a case where a pixel pitch is very small, an aspect ratio of the color filter layer is large, and an influence of the taper state of the side surface is large.

Therefore, an object of the present disclosure is to provide a display device including a plurality of light emitting elements each having a configuration and a structure in which color shift and color mixing are unlikely to occur.

### Solutions to Problems

A display device according to a first or second aspect of the present disclosure for achieving the above object is formed by arranging, on a base body, a plurality of light emitting element groups each including:

a first light emitting element including a first light emitting region and a first color filter layer disposed above the first light emitting region;

a second light emitting element including a second light emitting region and a second color filter layer disposed above the second light emitting region; and

a first light emitting element including a third light emitting region and a third color filter layer disposed above the third light emitting region.

In addition, in the display device of the first aspect of the present disclosure, in adjacent light emitting elements, an angle (θ) formed by the shortest line segment connecting a boundary line of a bottom surface of a color filter layer facing a light emitting region and an end of the light emitting region with a normal line of the base body is the same in the light emitting elements. Furthermore, in the display device of the second aspect of the present disclosure, in adjacent light emitting elements, a distance (L) from an orthogonal projection image of a boundary line of a bottom surface of a color filter layer facing a light emitting region onto the base body to an orthogonal projection image of an end of the light emitting region onto the base body is the same in the light emitting elements.

### BRIEF DESCRIPTION OF DRAWINGS

FIG. 1 is a diagram schematically illustrating an arrangement of color filter layers in a display device of a first embodiment, and a conceptual cross-sectional view of the display device of the first embodiment.

FIG. 2 is a diagram schematically illustrating an arrangement of the color filter layers in the display device of the first embodiment, and a conceptual cross-sectional view of the display device of the first embodiment.

FIG. 3 is a diagram schematically illustrating an arrangement of light emitting regions in the display device of the first embodiment.

FIG. 4 is a conceptual cross-sectional view of the display device of the first embodiment for explaining that color mixing is unlikely to occur in the display device of the first embodiment.

FIG. 5 is a diagram schematically illustrating an arrangement of color filter layers in a display device of a second embodiment, and various conceptual cross-sectional views of the display device of the second embodiment.

FIG. 6 is a diagram schematically illustrating an arrangement of color filter layers in the display device of the second embodiment, and various conceptual cross-sectional views of the display device of the second embodiment.

FIG. 7 is a diagram schematically illustrating an arrangement of light emitting regions in the display device of the second embodiment.

FIG. 8 is various conceptual cross-sectional views of the display device of the second embodiment for explaining that color mixing is unlikely to occur in the display device of the second embodiment.

FIG. 9 is various conceptual cross-sectional views of the display device of the second embodiment for explaining that color mixing is unlikely to occur in the display device of the second embodiment.

FIG. 10 is various conceptual cross-sectional views of the display device of the second embodiment for explaining that color mixing is unlikely to occur in the display device of the second embodiment.

FIG. 11 is various conceptual cross-sectional views of the display device of the second embodiment for explaining that color mixing is unlikely to occur in the display device of the second embodiment.

FIGS. 12A, 12B, and 12C are diagrams for explaining a mechanism by which color mixing occurs in the display device of the second embodiment and a conventional display device.

FIG. 13 is a diagram schematically illustrating an arrangement of color filter layers in a display device of a third embodiment, and various conceptual cross-sectional views of the display device of the third embodiment.

FIG. 14 is a diagram schematically illustrating an arrangement of color filter layers in the display device of the third embodiment, and various conceptual cross-sectional views of the display device of the third embodiment.

FIG. 15 is a diagram schematically illustrating an arrangement of light emitting regions in the display device of the third embodiment.

FIG. 16 is a diagram schematically illustrating an arrangement of color filter layers in a display device of a fourth embodiment, and various conceptual cross-sectional views of the display device of the third embodiment.

FIGS. 17A, 17B, 17C, 17D, 17E, 17F, and 17G are schematic partial cross-sectional views of various color filter layers.

FIG. 18 is a schematic partial cross-sectional view of the display device of the first embodiment.

FIG. 19 is a diagram schematically illustrating an arrangement of light emitting regions as a modification in the display device of the second embodiment.

FIGS. 20A and 20B illustrate an example in which the display device of the present disclosure is applied to a lens interchangeable single-lens reflex type digital still camera. FIG. 20A illustrates a front view of the digital still camera, and FIG. 20B illustrates a rear view thereof.

FIG. 21 is an external view of a head mounted display illustrating an example in which the display device of the present disclosure is applied to the head mounted display.

FIG. 22 is a diagram schematically illustrating an arrangement of color filter layers in a conventional display device, and various conceptual cross-sectional views of the conventional display device.

FIG. 23 is various conceptual cross-sectional views of the conventional display device for explaining that color mixing occurs in the conventional display device.

FIGS. 24A and 24B are conceptual diagrams of light emitting elements of a first example and a second example each having a resonator structure.

FIGS. 25A and 25B are conceptual diagrams of light emitting elements of a third example and a fourth example each having a resonator structure.

FIGS. 26A and 26B are conceptual diagrams of light emitting elements of a fifth example and a sixth example each having a resonator structure.

FIG. 27A is a conceptual diagram of a light emitting element of a seventh example having a resonator structure, and FIGS. 27B and 27C are conceptual diagrams of a light emitting element of an eighth example having a resonator structure.

### MODE FOR CARRYING OUT THE INVENTION

Hereinafter, the present disclosure will be described on the basis of embodiments with reference to the drawings. However, the present disclosure is not limited to the embodiments, and various numerical values and materials in the embodiments are illustrative. Note that description will be made in the following order.

1. General description of display devices according to first and second aspects of the present disclosure

2. First embodiment (display devices according to first and second aspects of the present disclosure)

3. Second embodiment (modification of first embodiment)

4. Third embodiment (another modification of first embodiment)

5. Fourth embodiment (still another modification of first embodiment)

6. Others

<General Description of Display Devices According to First and Second Aspects of the Present Disclosure>

In display devices according to first and second aspects of the present disclosure, the area (Sₜₒₚ) of an orthogonal projection image of a top surface region of a color filter layer surrounded by a boundary line between a top surface of a color filter layer (light emitting surface) and a top surface of a color filter layer (light emitting surface) onto a base body (or a first substrate or a second substrate described later) can be the same in a first light emitting element, a second light emitting element, and a third light emitting element. In addition, in this case, the area (S_{EL}) of a light emitting region can be different among the first light emitting element, the second light emitting element, and the third light emitting element.

Alternatively, in the display devices according to the first and second aspects of the present disclosure, the area (Sₜₒₚ) of an orthogonal projection image of a top surface region of a color filter layer surrounded by a boundary line between a top surface of a color filter layer (light emitting surface) and a top surface of a color filter layer (light emitting surface) onto a base body (or a first substrate or a second substrate described later) can be different among the first light emitting element, the second light emitting element, and the third light emitting element. In addition, in this case, the area (S_{EL}) of a light emitting region can be the same in the first light emitting element, the second light emitting element, and the third light emitting element.

In the display devices according to the first and second aspects of the present disclosure including various preferable modes described above, the first light emitting region, the second light emitting region, and the third light emitting region may emit white light. Alternatively, the first light emitting region may emit red light, the second light emitting region may emit green light, and the third light emitting region may emit blue light. However, the present disclosure is not limited thereto, and it is also possible to add a fourth light emitting element that emits white light, or a fourth light emitting element that emits light of a color other than red light, green light, and blue light.

The following can be exemplified as an arrangement and an arrangement state of the first light emitting element, the second light emitting element, and the third light emitting element. That is,

the first light emitting elements constituting the plurality of light emitting element groups may be arranged in a first direction,

the second light emitting elements constituting the plurality of light emitting element groups may be arranged in the first direction, and

the third light emitting elements constituting the plurality of light emitting element groups may be arranged in the first direction (so-called stripe arrangement). Alternatively,

the light emitting element group may be constituted by four light emitting elements arranged in 2×2,

the first light emitting element may be arranged adjacent to the two third light emitting elements,

the second light emitting element may be arranged adjacent to the two third light emitting elements, and

each of the two third light emitting elements may be arranged adjacent to the first light emitting element and the second light emitting element (so-called diagonal arrangement). In this case, the light emitting element group occupies, for example, a rectangular region. Alternatively,

the light emitting element group may be constituted by the one first light emitting element, the one second light emitting element, and the one third light emitting element,

the first light emitting element may be arranged adjacent to the second light emitting element and the third light emitting element, and

the second light emitting element may be arranged adjacent to the first light emitting element and the third light emitting element. Note that in this case, the light emitting element group occupies, for example, a rectangular region. Alternatively, the arrangement of the first light emitting element, the second light emitting element, and the third light emitting element may be a stripe arrangement, a delta arrangement, a rectangle arrangement, or a pentile arrangement.

In the display device of the first aspect of the present disclosure, in adjacent light emitting elements, an angle (θ) formed by the shortest line segment connecting a boundary line of a bottom surface of a color filter layer facing a light emitting region and an end of the light emitting region with a normal line of the base body (or a first substrate or a second substrate described later) is the same in the light emitting elements. Furthermore, in the display device of the second aspect of the present disclosure, in adjacent light emitting elements, a distance (L) from an orthogonal projection image of a boundary line of a bottom surface of a color filter layer facing a light emitting region onto the base body (or a first substrate or a second substrate described later) to an orthogonal projection image of an end of the light emitting region onto the base body (or the first substrate or the second substrate described later) is the same in the light emitting elements. Here, “same” means the following. That is, for example, in five regions including central parts of four quadrants obtained by dividing the display device into four regions of a first quadrant, a second quadrant, a third quadrant, and a first quadrant, and the origin, one or more light emitting element groups are appropriately selected. In the selected light emitting element group, the angle (θ) or the distance (L) in each light emitting element is determined. Moreover, an average value θₐᵥₑ, Lₐᵥₑ and a standard deviation σ_{angle}, σ_{distance} of the angle (θ) or the distance (L) are determined. Then,

when σ_{angle}/θₐᵥₑ≤0.015 and

σ_{distance}/Lₐᵥₑ≤0.2 are satisfied,

it is regarded as “same”, and

when σ_{angle}/θₐᵥₑ>0.015 and

σ_{distance}/Lₐᵥₑ>0.2 are satisfied,

it is regarded as “different”. However, these requirements are illustrative. For example, in a case where θₐᵥₑ=76 degrees and σ_{angle}=1.125 degrees, when a value of eave changes by ±5 degrees or more from a design value, it is regarded as “different”. In a case where an end region of an adjacent color filter layer is overlaid on an end region of a certain color filter layer, the end of the certain color filter layer is defined as a boundary line of a bottom surface.

In the display devices according to the first and second aspects of the present disclosure including the preferable modes and configurations described above (hereinafter, these are collectively referred to as “the display device or the like of the present disclosure”), in a boundary region between adjacent color filter layers, a structure constituted by a transparent resin (constituted by a transparent resin layer, see, for example, Japanese Patent Application Laid-Open No. 2014-089804) may be disposed at a bottom including a bottom surface of the color filter layer. The color filter layer is constituted by a resin (for example, a photocurable resin) to which a coloring agent containing a desired pigment or dye is added. By selecting a pigment or a dye, adjustment is performed such that light transmittance in a target wavelength range of red, green, blue, or the like is high, and light transmittance in the other wavelength ranges is low. Such a color filter layer may be constituted by a known color resist material. In a light emitting element that emits white light, it is only required to dispose a transparent filter.

The display device or the like of the present disclosure is a top emission type display device that emits light from a second substrate. In the top emission type display device, for example, it is only required to form a color filter layer above a first substrate, but the color filter layer may be disposed on a side of the first substrate (on-chip color filter layer structure (OCCF structure)), or may be disposed on a side of the second substrate. In another expression, the display device or the like of the present disclosure includes the first substrate, the second substrate, and an image display unit sandwiched by the first substrate and the second substrate. In the image display unit, a plurality of the light emitting elements including the preferable modes and configurations described above is arranged in a two-dimensional matrix. Here, the light emitting elements are formed on a side of the first substrate.

Specifically, each of the light emitting elements in the display device or the like of the present disclosure includes a first electrode, an organic layer formed on the first electrode, a second electrode formed on the organic layer, a protective layer (flattening layer) formed on the second electrode, and a color filter layer formed on the protective layer. In addition, light from the organic layer is emitted to the outside via the second electrode, the protective layer, and the color filter layer. The first electrode is disposed for each of the light emitting elements. The organic layer is disposed for each of the light emitting elements, or is disposed while being shared by the light emitting elements. The second electrode is disposed while being shared by the light emitting elements. That is, the second electrode is a so-called solid electrode. The first substrate is disposed below the base body, and the second substrate is disposed on or above a top surface of the color filter layer. The light emitting region is disposed on the base body.

In the display device or the like of the present disclosure, the first electrode may be in contact with a part of the organic layer, or a part of the first electrode may be in contact with the organic layer. In these cases, specifically, the first electrode may be smaller than the organic layer, the first electrode may have the same size as the organic layer, the first electrode may be larger than the organic layer, or an insulating layer may be formed between an edge of the first electrode and the organic layer. A region where the first electrode is in contact with the organic layer is the light emitting region.

In a case where the first light emitting region, the second light emitting region, and the third light emitting region emit white light, the organic layer emits white light. In this case, the organic layer may have a laminated structure constituted by a red light emitting layer, a green light emitting layer, and a blue light emitting layer. Alternatively, the organic layer may have a structure obtained by laminating two layers of a blue light emitting layer that emits blue light and a yellow light emitting layer that emits yellow light, and emits white light as a whole. Alternatively, the organic layer may have a structure obtained by laminating two layers of a blue light emitting layer that emits blue light and an orange light emitting layer that emits orange light, and emits white light as a whole.

In the display device or the like of the present disclosure, as described above, the organic layer may be constituted by at least two light emitting layers that emit different colors. In this case, light emitted from the organic layer may be white light. Specifically, the organic layer may have a structure obtained by laminating three layers of a red light emitting layer that emits red light (wavelength: 620 nm to 750 nm), a green light emitting layer that emits green light (wavelength: 495 nm to 570 nm), and a blue light emitting layer that emits blue light (wavelength: 450 nm to 495 nm), and emits white light as a whole. Alternatively, the organic layer may have a structure obtained by laminating two layers of a blue light emitting layer that emits blue light and a yellow light emitting layer that emits yellow light, and emits white light as a whole. Alternatively, the organic layer may have a structure obtained by laminating two layers of a blue light emitting layer that emits blue light and an orange light emitting layer that emits orange light, and emits white light as a whole. In addition, such an organic layer that emits white light is combined with a red color filter layer to constitute a red light emitting element. The organic layer that emits white light is combined with a green color filter layer to constitute a green light emitting element. The organic layer that emits white light is combined with a blue color filter layer to constitute a blue light emitting element. A combination of sub-pixels such as a red light emitting element, a green light emitting element, and a blue light emitting element constitutes one pixel. In some cases, a red light emitting element, a green light emitting element, a blue light emitting element, and a light emitting element that emits white light (or a light emitting element that emits complementary color light) may constitute one pixel. In a mode constituted by at least two light emitting layers that emit light of different colors, there is actually a case where the light emitting layers that emit light of different colors are mixed and are not clearly separated into the layers.

Alternatively, the organic layer may be constituted by one light emitting layer. In this case, for example, the light emitting element may be constituted by a red light emitting element having an organic layer including a red light emitting layer, a green light emitting element having an organic layer including a green light emitting layer, or a blue light emitting element having an organic layer including a blue light emitting layer. In addition, these three kinds of light emitting elements (sub-pixels) constitute one pixel.

Examples of a material constituting the protective layer (flattening layer) include an acrylic resin, SiN, SiON, SiC, amorphous silicon (α-Si), Al₂O₃, and TiO₂. The protective layer can be formed on the basis of a known method such as various CVD methods, various coating methods, various PVD methods including a sputtering method and a vacuum vapor deposition method, or various printing methods including a screen printing method. Furthermore, as the method for forming the protective layer, an atomic layer deposition (ALD) method can also be adopted. The protective layer may be shared by the plurality of light emitting elements, or may be individually disposed in each of the light emitting elements. The protective layer and the second substrate are bonded to each other, for example, via a resin layer (sealing resin layer). Examples of a material constituting the resin layer (sealing resin layer) include a thermosetting adhesive such as an acrylic adhesive, an epoxy-based adhesive, a urethane-based adhesive, a silicone-based adhesive, or a cyanoacrylate-based adhesive, and an ultraviolet curable adhesive.

On an outermost surface (specifically, an outer surface of the second substrate) that emits light in the display device, an ultraviolet absorbing layer, a contamination preventing layer, a hard coat layer, and an antistatic layer may be formed, or a protective member (for example, cover glass) may be disposed.

Moreover, in the display device or the like of the present disclosure, an on-chip microlens may be disposed on a light emitting side. By disposing the on-chip microlens, light from the organic layer can be diverged in a desired state, and as a result, viewing angle characteristics can be controlled. The on-chip microlens can be constituted, for example, by a known transparent resin material such as an acrylic resin, and can be obtained by melt-flowing the transparent resin material, or can be obtained by etching back the transparent resin material, by a combination of a photolithography technique using a gray tone mask and an etching method, or by a method for forming the transparent resin material into a lens shape on the basis of a nanoprint method.

In the display device or the like of the present disclosure, the base body is formed on or above the first substrate. Examples of a material constituting the base body include an insulating material such as SiO₂, SiN, or SiON. Alternatively, it is only required to constitute the base body by an insulating material having an etching selectivity with an insulating layer and the like formed on or above the base body. The base body can be formed by a forming method suitable for a material constituting the base body, specifically, for example, on the basis of a known method such as various CVD methods, various coating methods, various PVD methods including a sputtering method and a vacuum vapor deposition method, various printing methods including a screen printing method, a plating method, an electrodeposition method, an immersion method, or a sol-gel method.

Under or below the base body, a light emitting element driving unit is disposed although the present disclosure is not limited thereto. For example, the light emitting element driving unit includes a transistor (specifically, for example, MOSFET) formed on a silicon semiconductor substrate constituting the first substrate or a thin film transistor (TFT) disposed on various substrates each constituting the first substrate. The transistor and the TFT constituting the light emitting element driving unit may be connected to the first electrode via a contact hole (contact plug) formed in the base body. The light emitting element driving unit may have a known circuit configuration. The second electrode is connected to the light emitting element driving unit via a contact hole (contact plug) formed in the base body at an outer periphery of the display device. The light emitting elements are formed on a side of the first substrate. As described above, the second electrode may be an electrode shared by the plurality of light emitting elements. That is, the second electrode may be a so-called solid electrode.

The first substrate or the second substrate may be constituted by a silicon semiconductor substrate, a high strain point glass substrate, a soda glass (Na₂O.CaO.SiO₂) substrate, a borosilicate glass (Na₂O.B₂O₃.SiO₂) substrate, a forsterite (2MgO.SiO₂) substrate, a lead glass (Na₂O.PbO.SiO₂) substrate, various glass substrates each having an insulation material layer formed on a surface thereof, a quartz substrate, a quartz substrate having an insulation material layer formed on a surface thereof, or an organic polymer such as polymethyl methacrylate (PMMA), polyvinyl alcohol (PVA), polyvinyl phenol (PVP), polyether sulfone (PES), polyimide, polycarbonate, or polyethylene terephthalate (PET) (having a mode of a polymer material such as a plastic film, a plastic sheet, or a plastic substrate constituted by a polymer material and having flexibility). Materials constituting the first substrate and the second substrate may be the same as or different from each other. However, the second substrate is required to be transparent to light emitted from the light emitting element.

In a case where the first electrode is caused to function as an anode electrode, examples of a material constituting the first electrode include a metal having high work function, such as platinum (Pt), gold (Au), silver (Ag), chromium (Cr), tungsten (W), nickel (Ni), copper (Cu), iron (Fe), cobalt (Co), or tantalum (Ta), or an alloy thereof (for example, an Ag—Pd—Cu alloy containing silver as a main component and containing 0.3% by mass to 1% by mass of palladium (Pd) and 0.3% by mass to 1% by mass of copper (Cu), an Al—Nd alloy, or an Al—Cu alloy). Moreover, in a case of using a conductive material having a small work function value and high light reflectivity, such as aluminum (Al) or an alloy containing aluminum, by improving a hole injection property, for example, by disposing an appropriate hole injection layer, the first electrode can be used as an anode electrode. The thickness of the first electrode may be 0.1 μm to 1 μm, for example. Alternatively, in a case where a light reflecting layer described later is disposed, examples of a material constituting the first electrode include various transparent conductive materials such as a transparent conductive material including, for a base layer, indium oxide, indium-tin oxide (ITO, including Sn-doped In₂O₃, crystalline ITO, and amorphous ITO), indium zinc oxide (IZO), indium-gallium oxide (IGO), indium-doped gallium-zinc oxide (IGZO, In—GaZnO₄), IFO (F-doped In₂O₃), ITiO (Ti-doped In₂O₃), InSn, InSnZnO, tin oxide (SnO₂), ATO (Sb-doped SnO₂), FTO (F-doped SnO₂), zinc oxide (ZnO), aluminum oxide-doped zinc oxide (AZO), gallium-doped zinc oxide (GZO), B-doped ZnO, AlMgZnO (aluminum oxide and magnesium oxide-doped zinc oxide), antimony oxide, titanium oxide, NiO, spinel type oxide, oxide having a YbFe₂O₄ structure, gallium oxide, titanium oxide, niobium oxide, nickel oxide, or the like. Alternatively, the first electrode may have a structure obtained by laminating a transparent conductive material having excellent hole injection characteristics, such as an oxide of indium and tin (ITO) or an oxide of indium and zinc (IZO) on a dielectric multilayer film or a reflective film having high light reflectivity, including aluminum (Al) or the like. Meanwhile, in a case where the first electrode is caused to function as a cathode electrode, the first electrode is desirably constituted by a conductive material having a small work function value and high light reflectivity. However, by improving an electron injection property, for example, by disposing an appropriate electron injection layer in a conductive material having high light reflectivity used as an anode electrode, the first electrode can also be used as a cathode electrode.

In a case where the second electrode is caused to function as a cathode electrode, a material constituting the second electrode (a semi-light transmitting material or a light transmitting material) is desirably constituted by a conductive material having a small work function value so as to be able to transmit emitted light and inject an electron into an organic layer (light emitting layer) efficiently. Examples of the material constituting the second electrode include a metal having a small work function and an alloy thereof, such as aluminum (Al), silver (Ag), magnesium (Mg), calcium (Ca), sodium (Na), strontium (Sr), an alkali metal or an alkaline earth metal and silver (Ag) [for example, an alloy of magnesium (Mg) and silver (Ag) (Mg—Ag alloy)], an alloy of magnesium-calcium (Mg—Ca alloy), or an alloy of aluminum (Al) and lithium (Li) (Al—Li alloy). Among these materials, an Mg—Ag alloy is preferable, and a volume ratio between magnesium and silver may be Mg:Ag=5:1 to 30:1, for example. Alternatively, as a volume ratio between magnesium and calcium may be Mg:Ca=2:1 to 10:1, for example. The thickness of the second electrode may be 4 nm to 50 nm, preferably 4 nm to 20 nm, and more preferably 6 nm to 12 nm, for example. Alternatively, the material constituting the second electrode may be at least one material selected from the group consisting of Ag—Nd—Cu, Ag—Cu, Au, and Al—Cu. Alternatively, the second electrode can have a laminated structure constituted by, from the organic layer side, the material layer described above and a so-called transparent electrode (for example, thickness 3×10⁻⁸ m to 1×10⁻⁶ m) including, for example, ITO or IZO. A bus electrode (auxiliary electrode) including a low resistance material such as aluminum, an aluminum alloy, silver, a silver alloy, copper, a copper alloy, gold, or a gold alloy may be disposed in the second electrode to reduce resistance as the whole second electrode. Average light transmittance of the second electrode is 50% to 90%, and preferably 60% to 90%. Meanwhile, in a case where the second electrode is caused to function as an anode electrode, the second electrode is desirably constituted by a conductive material that transmits emitted light and has a large work function value.

Examples of a method for forming the first electrode or the second electrode include a combination of a vapor deposition method including an electron beam vapor deposition method, a hot filament vapor deposition method, and a vacuum vapor deposition method, a sputtering method, a chemical vapor deposition method (CVD method), an MOCVD method, and an ion plating method with an etching method; various printing methods such as a screen printing method, an inkjet printing method, and a metal mask printing method; a plating method (an electroplating method or an electroless plating method); a lift-off method; a laser ablation method; and a sol-gel method. According to various printing methods and a plating method, the first electrode or the second electrode having a desired shape (pattern) can be formed directly. Note that, in a case where the second electrode is formed after the organic layer is formed, the second electrode is preferably formed particularly on the basis of a film formation method in which energy of film formation particles is small, such as a vacuum vapor deposition method, or a film formation method such as an MOCVD method from a viewpoint of preventing the organic layer from being damaged. When the organic layer is damaged, non-light emitting pixels (or non-light emitting sub-pixels) called “dark spots” due to generation of a leak current may be generated.

The organic layer includes a light emitting layer containing an organic light emitting material. Specifically, for example, the organic layer may be constituted by a laminated structure of a hole transport layer, a light emitting layer, and an electron transport layer, a laminated structure of a hole transport layer and a light emitting layer serving also as an electron transport layer, a laminated structure of a hole injection layer, a hole transport layer, a light emitting layer, an electron transport layer, and an electron injection layer or the like. Examples of a method for forming the organic layer include a physical vapor deposition method (PVD method) such as a vacuum vapor deposition method; a printing method such as a screen printing method or an inkjet printing method; a laser transfer method in which an organic layer on a laser absorption layer is separated by irradiating a laminated structure of the laser absorption layer and the organic layer formed on a transfer substrate with a laser and the organic layer is transferred; and various coating methods. In a case where the organic layer is formed on the basis of the vacuum vapor deposition method, for example, using a so-called metal mask, the organic layer can be obtained by depositing a material that has passed through an opening disposed in the metal mask.

In the display device or the like of the present disclosure, an insulating layer and an interlayer insulating layer are formed. Examples of an insulating material constituting the insulating layer and the interlayer insulating layer include a SiOₓ-based material (material constituting a silicon-based oxide film) such as SiO₂, non-doped silicate glass (NSG), borophosphosilicate glass (BPSG), PSG, BSG, AsSG, SbSG, PbSG, spin on glass (SOG), low temperature oxide (LTO, low temperature CVD-SiO₂), low melting point glass, or glass paste; a SiN-based material including a SiON-based material; SiOC; SiOF; and SiCN. Alternatively, examples of the material include an inorganic insulating material such as titanium oxide (TiO₂), tantalum oxide (Ta₂O₅), aluminum oxide (Al₂O₃), magnesium oxide (MgO), chromium oxide (CrOₓ), zirconium oxide (ZrO₂), niobium oxide (Nb₂O₅), tin oxide (SnO₂), or vanadium oxide (VO). Alternatively, examples of the insulating material further include various resins such as a polyimide-based resin, an epoxy-based resin, and an acrylic resin; and a low dielectric constant insulating material such as SiOCH, organic SOG, or a fluorine-based resin (for example, a material having a dielectric constant k (=ε/ε₀) of 3.5 or less, for example, and specific examples thereof include fluorocarbon, cycloperfluorocarbon polymer, benzocyclobutene, cyclic fluororesin, polytetrafluoroethylene, amorphous tetrafluoroethylene, polyaryl ether, fluorinated aryl ether, fluorinated polyimide, amorphous carbon, parylene (polyparaxylylene), and fluorinated fullerene). Examples of the insulating material further include Silk (trademark of The Dow Chemical Co., coating type low dielectric constant interlayer insulation film material) and Flare (trademark of Honeywell Electronic Materials Co., polyallyl ether (PAE)-based material). In addition, these materials can be used singly or in appropriate combination thereof. In some cases, the base body may be constituted by the materials described above. The insulating layer, the interlayer insulating layer, and the base body can be formed by a known method such as various CVD methods, various coating methods, various PVD methods including a sputtering method and a vacuum vapor deposition method, various printing methods such as a screen printing method, a plating method, an electrodeposition method, an immersion method, or a sol-gel method.

The display device or the like of the present disclosure including the various preferable modes and configurations described above may be constituted by an organic electroluminescence display device (organic EL display device). The light emitting element may be constituted by an organic electroluminescence element (organic EL element)

In order to further improve a light extraction efficiency, the organic EL display device preferably has a resonator structure. Specifically, light emitted from the light emitting layer is caused to resonate between a first interface constituted by an interface between the first electrode and the organic layer (or a first interface constituted by an interface between the light reflecting layer and the interlayer insulating layer in a structure in which the interlayer insulating layer is disposed under the first electrode, and the light reflecting layer is disposed under the interlayer insulating layer) and a second interface constituted by an interface between the second electrode and the organic layer, and a part of the light is emitted from the second electrode. In addition, if a distance from a maximum emission position of the light emitting layer to the first interface is represented by L₁, an optical distance thereof is represented by OL₁, a distance from the maximum emission position of the light emitting layer to the second interface is represented by L₂, an optical distance thereof is represented by OL₂, and m₁ and m₂ each represent an integer, the following formulas (1-1) and (1-2) are satisfied.

0.7{−ϕ₁/(2π)+m₁}≤2×OL₁/λ≤1.2{−ϕ₁/(2π)+m₁} (1-1)

0.7{−ϕ₂/(2π)+m₂}≤2×OL₂/λ≤1.2{−ϕ₂/(2π)+m₂} (1-2)

Here,

λ: Maximum peak wavelength of a spectrum of light generated in light emitting layer (or a desired wavelength among wavelengths of light generated in light emitting layer)

ϕ₁: Phase shift amount (unit: radian) of light reflected on first interface Provided that −2π<ϕ₁≤0 is satisfied.

ϕ₂: Phase shift amount (unit: radian) of light reflected on second interface Provided that −2π<ϕ₂≤0 is satisfied.

Here, the value of m₁ is a value of 0 or more, and the value of m₂ is a value of 0 or more independently of the value of m₁. Examples of (m₁, m₂) include (m₁, m₂)=(0, 0), (m₁, m₂)=(0, 1), (m₁, m₂)=(1, 0), and (m₁, m₂)=(1, 1).

The distance L₁ from the maximum emission position of the light emitting layer to the first interface means an actual distance (physical distance) from the maximum emission position of the light emitting layer to the first interface, and the distance L₂ from the maximum emission position of the light emitting layer to the second interface means an actual distance (physical distance) from the maximum emission position of the light emitting layer to the second interface. Furthermore, the optical distance is also called an optical path length, and generally means n×L when a light ray passes through a medium having a refractive index n for a distance L. The same applies to the following description. Therefore, if an average refractive index is represented by nₐᵥₑ, the following relations are satisfied.

OL₁=L₁×nₐᵥₑ

OL₂=L₂×nₐᵥₑ

Here, the average refractive index nₐᵥₑ is obtained by summing up a product of the refractive index and the thickness of each layer constituting the organic layer (or the organic layer, the first electrode, and the interlayer insulating layer), and dividing the resulting sum by the thickness of the organic layer (or the organic layer, the first electrode, and the interlayer insulating layer).

The first electrode or the light reflecting layer and the second electrode absorb a part of incident light and reflect the rest. Therefore, a phase shift occurs in the reflected light. The phase shift amounts ϕ₁ and ϕ₂ can be determined by measuring values of a real number part and an imaginary number part of a complex refractive index of a material constituting the first electrode or the light reflecting layer and the second electrode, for example, using an ellipsometer, and performing calculation based on these values (refer to, for example, “Principles of Optic”, Max Born and Emil Wolf, 1974 (PERGAMON PRESS)). The refractive index of the organic layer, the interlayer insulating layer, or the like can also be determined by measurement with an ellipsometer.

Examples of a material constituting the light reflecting layer include aluminum, an aluminum alloy (for example, Al—Nd or Al—Cu), an Al/Ti laminated structure, an Al—Cu/Ti laminated structure, chromium (Cr), silver (Ag), and a silver alloy (for example, Ag—Pd—Cu or Ag—Sm—Cu). The light reflecting layer can be formed, for example, by a vapor deposition method including an electron beam vapor deposition method, a hot filament vapor deposition method, and a vacuum vapor deposition method, a sputtering method, a CVD method, an ion plating method; a plating method (an electroplating method or an electroless plating method); a lift-off method; a laser ablation method; a sol-gel method; or the like.

As described above, in the organic EL display device having a resonator structure, actually, a red light emitting element constituted by combining an organic layer that emits white light with a red color filter layer causes red light emitted from the light emitting layer to resonate, and emits reddish light (light having a light spectrum peak in a red region) from the second electrode. Furthermore, a green light emitting element constituted by combining an organic layer that emits white light with a green color filter layer causes green light emitted from the light emitting layer to resonate, and emits greenish light (light having a light spectrum peak in a green region) from the second electrode. Moreover, a blue light emitting element constituted by combining an organic layer that emits white light with a blue color filter layer causes blue light emitted from the light emitting layer to resonate, and emits blueish light (light having a light spectrum peak in a blue region) from the second electrode. In other words, it is only required to design each of the light emitting elements by determining a desired wavelength λ (specifically, wavelengths of red light, green light, and blue light) among wavelengths of light generated in the light emitting layer and determining various parameters such as OL₁ and OL₂ in each of the red light emitting element, the green light emitting element, and the blue light emitting element on the basis of formulas (1-1) and (1-2). For example, paragraph [0041] of Japanese Patent Application Laid-Open No. 2012-216495 discloses an organic EL element having a resonator structure using an organic layer as a resonance part, and describes that the film thickness of the organic layer is preferably 80 nm or more and 500 nm or less, and more preferably 150 nm or more and 350 nm or less because a distance from a light emitting point (light emitting surface) to a reflection surface can be appropriately adjusted.

In an organic EL display device, the thickness of a hole transport layer (hole supply layer) and the thickness of an electron transport layer (electron supply layer) are desirably substantially equal to each other. Alternatively, the thickness of the electron transport layer (electron supply layer) may be larger than that of the hole transport layer (hole supply layer). As a result, an electron can be supplied sufficiently to the light emitting layer in an amount necessary for a high efficiency at a low driving voltage. In other words, by disposing a hole transport layer between the first electrode corresponding to an anode electrode and the light emitting layer, and forming the hole transport layer with a film thickness smaller than that of the electron transport layer, supply of holes can be increased. In addition, this makes it possible to obtain a carrier balance with no excess or deficiency of holes and electrons and a sufficiently large carrier supply amount. Therefore, a high luminous efficiency can be obtained. Furthermore, due to no excess or deficiency of holes and electrons, the carrier balance hardly collapses, drive deterioration is suppressed, and an emission lifetime can be prolonged.

The display device can be used, for example, as a monitor device constituting a personal computer, or a monitor device incorporated in a television receiver, a mobile phone, a personal digital assistant (PDA), or a game machine. Alternatively, the organic EL display device can be applied to an electronic view finder (EVF) or a head mounted display (HMD). Alternatively, the organic EL display device can constitute an image display device in electronic paper such as an electronic book or electronic newspaper, a bulletin board such as a signboard, a poster, or a blackboard, rewritable paper substituted for printer paper, a display unit of a home appliance, a card display unit of a point card and the like, an electronic advertisement, or an electronic POP. The display device of the present disclosure can be used as a light emitting device, and can constitute various lighting devices including a backlight device for a liquid crystal display device and a planar light source device. The head mounted display includes: for example,

(a) a frame mounted on the head of an observer; and

(b) an image display device attached to the frame.

The image display device includes:

(A) the display device of the present disclosure; and

(B) an optical device on which light emitted from the display device of the present disclosure is incident and from which the light is emitted.

The optical device includes:

(B-1) a light guide plate in which the light incident on the light guide plate from the display device of the present disclosure is propagated by total reflection and then the light is emitted from the light guide plate toward an observer;

(B-2) a first deflecting means (for example, including a volume hologram diffraction grating film) that deflects the light incident on the light guide plate such that the light incident on the light guide plate is totally reflected in the light guide plate; and

(B-3) a second deflecting means (for example, including a volume hologram diffraction grating film) that deflects the light propagated in the light guide plate by total reflection a plurality of times in order to emit the light propagated in the light guide plate by total reflection from the light guide plate.

### First Embodiment

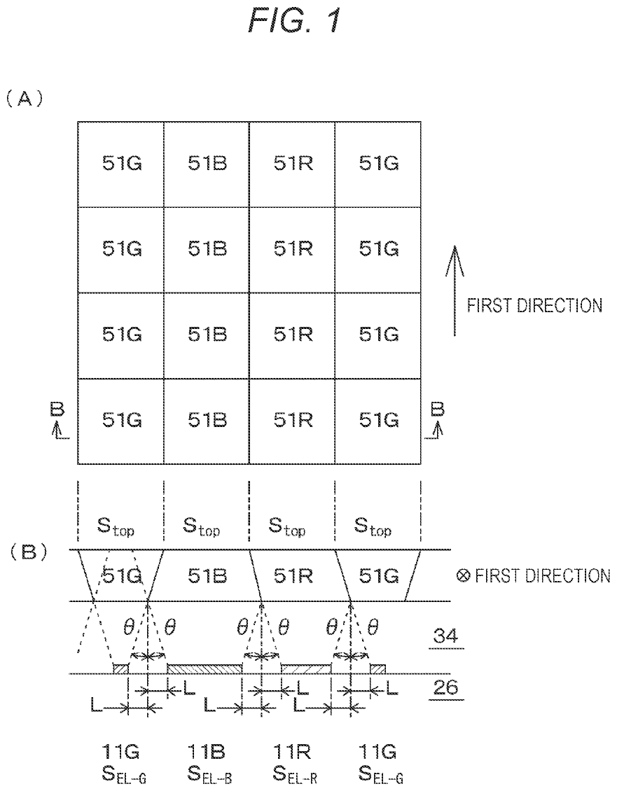

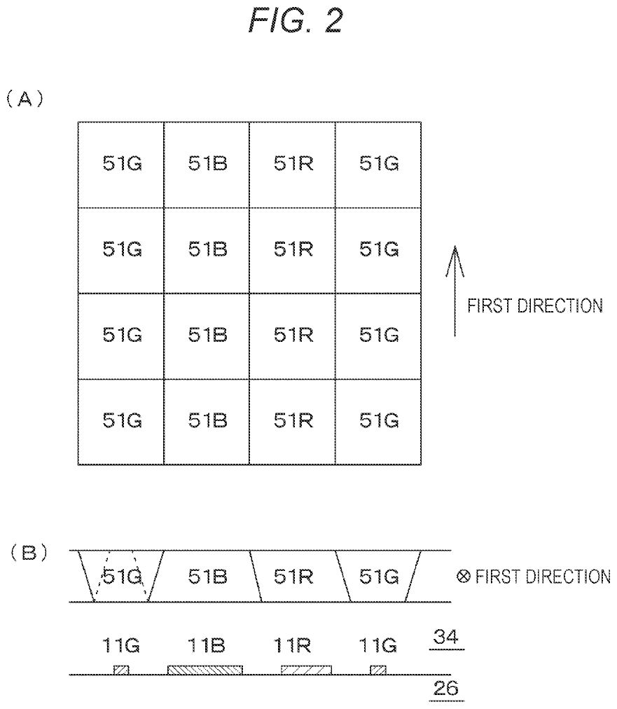

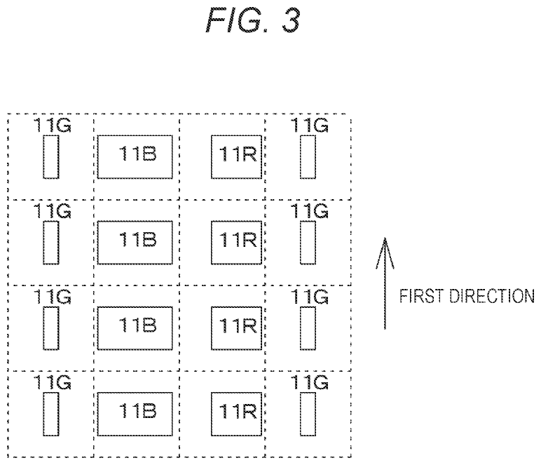

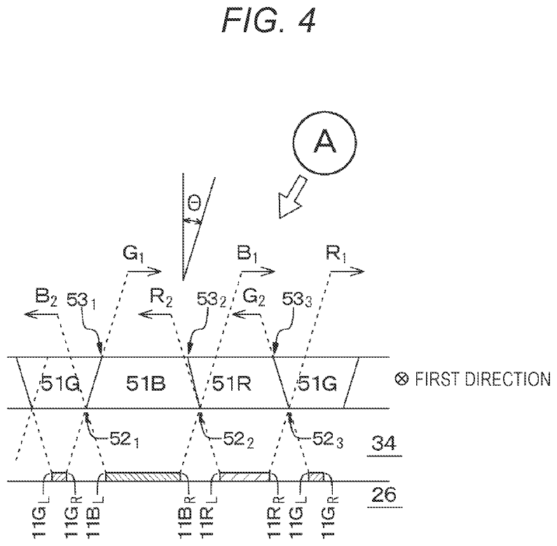

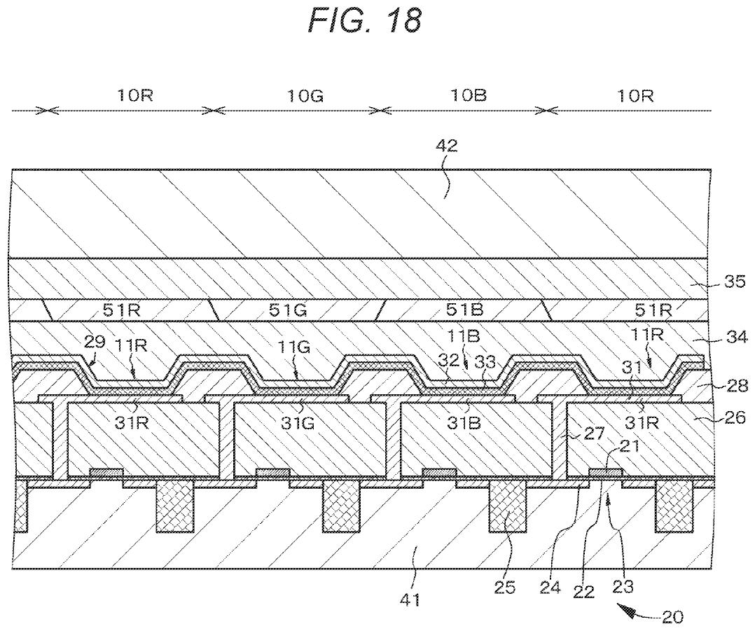

The first embodiment relates to display devices according to first and second aspects of the present disclosure. An arrangement of color filter layers in the display device of the first embodiment is schematically illustrated in (A) of FIG. 1 and (A) of FIG. 2, and a conceptual cross-sectional view of the display device of the first embodiment along the arrow B-B in (A) of FIG. 1 is illustrated in (B) of FIG. 1 and (B) of FIG. 2. Moreover, an arrangement of light emitting regions in the display device of the first embodiment is schematically illustrated in FIG. 3, and a conceptual cross-sectional view of the display device of the first embodiment for explaining that color mixing is unlikely to occur in the display device of the first embodiment is illustrated in FIG. 4. Furthermore, a schematic partial cross-sectional view of the display device of the first embodiment is illustrated in FIG. 18. Note that FIG. 18 illustrates the display device by ignoring a positional relationship between a color filter layer and a light emitting region. Specifically, the display device of the first embodiment is constituted by an organic EL display device, and the light emitting element is constituted by an organic EL element. Furthermore, the display device of the first embodiment is a top emission type display device that emits light from the second substrate, in which a color filter layer is disposed on a side of the first substrate. That is, the color filter layer has an on-chip color filter layer structure (OCCF structure).

A display device according to the first embodiment or the second to fourth embodiments described later is formed by arranging, on a base body 26, a plurality of light emitting element groups each including:

a first light emitting element 10R including a first light emitting region 11R and a first color filter layer 51R disposed above the first light emitting region 11R;

a second light emitting element 10G including a second light emitting region 11G and a second color filter layer 51G disposed above the second light emitting region 11G; and

a third light emitting element 10B including a third light emitting region 11B and a third color filter layer 51B disposed above the third light emitting region 11B.

In addition, to give explanation according to the display device of the first aspect of the present disclosure, in the display device of the first embodiment, in adjacent light emitting elements, an angle (θ) formed by the shortest line segment (indicated by dotted lines in (B) of FIG. 1 and FIG. 4) connecting a boundary line of a bottom surface of the color filter layer 51 facing the light emitting region 11 and an end of the light emitting region 11 with a normal line of the base body 26 (or a first substrate 41 or a second substrate 42) is the same in the light emitting elements 10R, 10G, and 10B. Furthermore, to give explanation according to the display device of the second aspect of the present disclosure, in adjacent light emitting elements, a distance (L) from an orthogonal projection image of a boundary line of a bottom surface of the color filter layer 51 facing the light emitting region 11 onto the base body 26 (or the first substrate 41 or the second substrate 42) to an orthogonal projection image of an end of the light emitting region 11 onto the base body 26 (or the first substrate 41 or the second substrate 42) is the same in the light emitting elements 10R, 10G, and 10B. Note that in (B) of FIG. 1, these orthogonal projection images are indicated by alternate long and short dash lines.

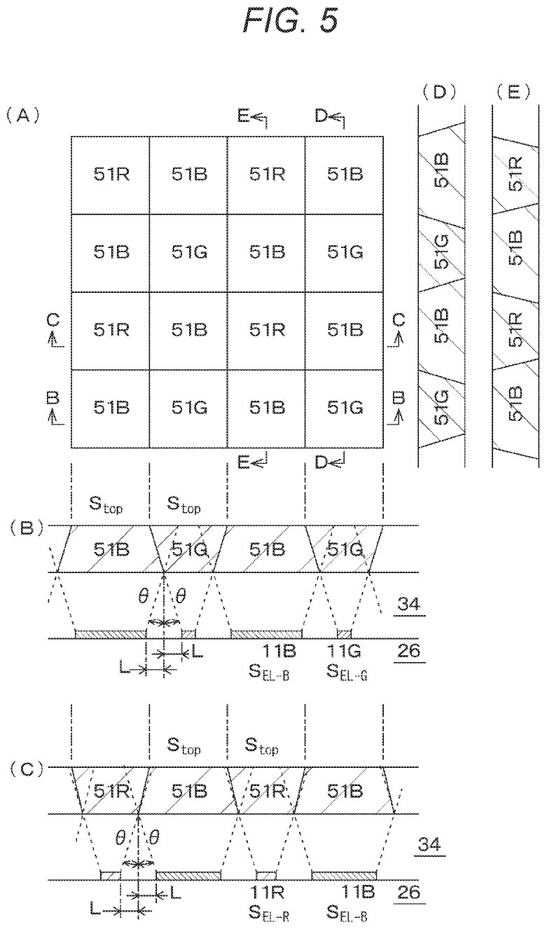

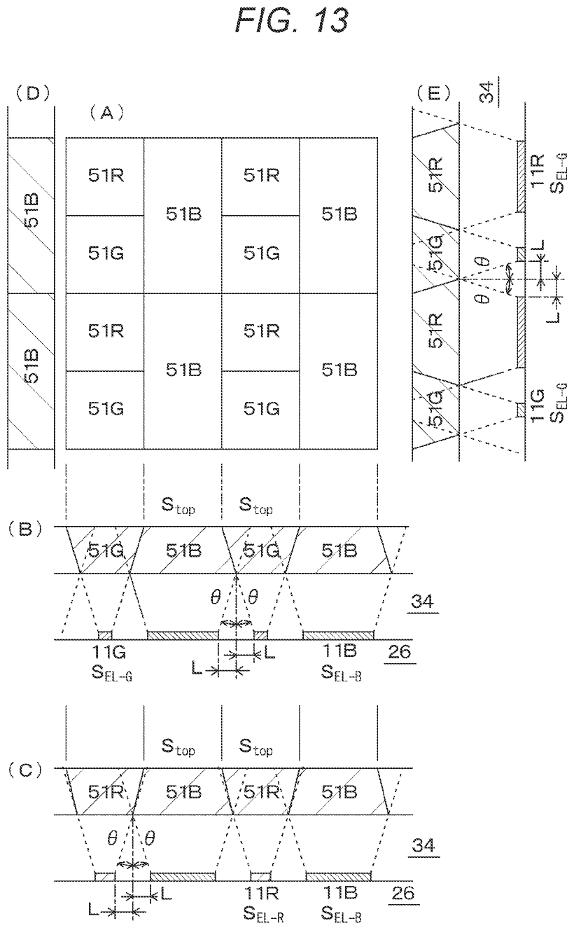

Here, in the display device according to the first embodiment or the second and third embodiments described later, the area (Sₜₒₚ) of an orthogonal projection image of a top surface region of the color filter layer 51R, 51G, 51B surrounded by a boundary line between a top surface of a color filter layer (light emitting surface) and a top surface of a color filter layer (light emitting surface) onto the base body 26 (or the first substrate 41 or the second substrate 42) is the same in the first light emitting element 10R, the second light emitting element 10G, and the third light emitting element 10B. In addition, the area (S_{EL-R}, S_{ER-G}, S_{EL-B}) of the light emitting region 11R, 11G, 11B is different among the first light emitting element 10R, the second light emitting element 10G, and the third light emitting element 10B. Specifically, as illustrated in (B) of FIG. 1, (B) and (C) of FIG. 5, and (B) and (C) of FIG. 13, S_{EL-G}<S_{ER-R}<S_{EL-B} is satisfied.

Furthermore, in the display device according to the first embodiment or the second to fourth embodiments described later, the first light emitting region 11R, the second light emitting region 11G, and the third light emitting region 11B emit white light.

One pixel is constituted by three light emitting elements of the first light emitting element 10R, the second light emitting element 10G, and the third light emitting element 10B. The first substrate 41 includes the color filter layers 51R, 51G, and 51B. That is, the light emitting region 11R, 11G, 11B emits white light, and the light emitting element 10R, 10G, 10B is constituted by a combination of the light emitting region 11R, 11G, 11B that emits white light and the color filter layer 51R, 51G, 51B. An organic layer 33 emits white light as a whole. The number of pixels is, for example, 1920×1080. One light emitting element (display element) constitutes one sub-pixel, and the number of light emitting elements (specifically, organic EL elements) is three times the number of pixels. The first light emitting element 10R includes the red color filter layer 51R and emits red light. The second light emitting element 10G includes the green color filter layer 51G and emits green light. The third light emitting element 10B includes the blue color filter layer 51B and emits blue light.

Moreover, in the display device of the first embodiment, the first light emitting elements 10R constituting the plurality of light emitting element groups are arranged in a first direction, the second light emitting elements 10G constituting the plurality of light emitting element groups are arranged in the first direction, and the third light emitting elements 10B constituting the plurality of light emitting element groups are arranged in the first direction. That is, in the display device of the first embodiment, the light emitting elements are arranged in a form of stripe arrangement. That is, the sub-pixels are arranged in a form of stripe arrangement.

In the display device according to the first embodiment or the second to fourth embodiments described later, specifically, each of the light emitting elements includes:

a first electrode 31 (31R, 31G, 31B);

an organic layer 33 formed on the first electrode 31;

a second electrode 32 formed on the organic layer 33;

a protective layer (flattening layer) 34 formed on the second electrode 32; and

a color filter layer 51 (51R, 51G, 51B) formed on the protective layer 34. In addition, light from the organic layer 33 is emitted to the outside via the second electrode 32, the protective layer 34, and the color filter layer 51.

Specifically, the first light emitting element 10R that emits red light includes:

the first electrode 31R;

the organic layer 33 formed on the first electrode 31R;

the second electrode 32 formed on the organic layer 33;

the protective layer (flattening layer) 34 formed on the second electrode 32; and

the color filter layer 51R formed on the protective layer 34. Furthermore, the second light emitting element 10G that emits green light includes:

the first electrode 31G;

the organic layer 33 formed on the first electrode 31G;

the second electrode 32 formed on the organic layer 33;

the protective layer (flattening layer) 34 formed on the second electrode 32; and

the color filter layer 51G formed on the protective layer 34. Moreover, the third light emitting element 10B that emits blue light includes:

the first electrode 31B;

the organic layer 33 formed on the first electrode 31B;

the second electrode 32 formed on the organic layer 33;

the protective layer (flattening layer) 34 formed on the second electrode 32; and

the color filter layer 51B formed on the protective layer 34.

The first electrodes 31R, 31G, and 31B are disposed for the light emitting elements 10R, 10G, and 10B, respectively. The second electrode 32 is disposed while being shared by the light emitting elements 10R, 10G, and 10B. That is, the second electrode 32 is a so-called solid electrode. The first substrate 41 is disposed below the base body 26 constituted by an insulating material, and the second substrate 42 is disposed above a top surface of the color filter layer 51R, 51G, 51B. The light emitting region 11 (11R, 11G, 11B) constituted by a region in which the first electrode 31 (31R, 31G, 31B) and the organic layer 33 formed on the first electrode 31 are in contact with each other is disposed on the base body 26. More specifically, the first electrode 31 (31R, 31G, 31B) is formed on the base body 26.

The light emitting element driving unit is disposed below the base body 26 containing SiON and formed on the basis of a CVD method. The light emitting element driving unit may have a known circuit configuration. The light emitting element driving unit is constituted by a transistor (specifically, MOSFET) formed on a silicon semiconductor substrate corresponding to the first substrate 41. The transistor 20 constituted by MOSFET includes a gate insulating layer 22 formed on the first substrate 41, a gate electrode 21 formed on the gate insulating layer 22, a source/drain region 24 formed on the first substrate 41, a channel forming region 23 formed between the source/drain regions 24, and an element isolating region 25 surrounding the channel forming region 23 and the source/drain region 24. The transistor 20 is electrically connected to the first electrode 31 via a contact plug 27 disposed in the base body 26. Note that one transistor 20 is illustrated for one light emitting element driving unit in the drawings.

Furthermore, as described above, the first electrode 31 is disposed on the base body 26 for each light emitting element. In addition, an insulating layer 28 having an opening 29 in which the first electrode 31 is exposed to a bottom is formed on the base body 26, and the organic layer 33 is formed at least on the first electrode 31 exposed to the bottom of the opening 29. Specifically, the organic layer 33 is formed so as to cover a portion from the first electrode 31 exposed to the bottom of the opening 29 to the insulating layer 28, and the insulating layer 28 is formed so as to cover a portion from the first electrode 31 to the base body 26. An actual light emitting portion of the organic layer 33 is surrounded by the insulating layer 28. That is, the region of the organic layer 33 surrounded by the insulating layer 28 corresponds to the light emitting region. The insulating layer 28 and the second electrode 32 are covered with a protective layer 34 containing SiN. The color filter layer 51 and the second substrate 42 are bonded to each other over the entire surface with a resin layer (sealing resin layer) 35 containing an acrylic adhesive.

The second electrode 32 is connected to the light emitting element driving unit via a contact hole (contact plug) (not illustrated) formed in the base body 26 at an outer periphery of the display device. Note that an auxiliary electrode connected to the second electrode 32 may be disposed below the second electrode 32 in the outer periphery of the display device, and the auxiliary electrode may be connected to the light emitting element driving unit.

The first electrode 31 functions as an anode electrode, and the second electrode 32 functions as a cathode electrode. The first electrode 31 includes a light reflecting material, specifically, an Al—Nd alloy. The second electrode 32 includes a transparent conductive material such as ITO. The first electrode 31 is formed on the basis of a combination of a vacuum vapor deposition method and an etching method. Furthermore, a film of the second electrode 32 is formed by a film formation method in which energy of film formation particles is small, such as a vacuum vapor deposition method. The first substrate 41 is constituted by a silicon semiconductor substrate, and the second substrate 42 is constituted by a glass substrate.

By the way, in forming a color filter layer, the color filter layer is usually constituted by a photocurable resin to which a colorant containing a desired pigment or dye is added. Then, for example, the color filter layer is formed on the protective layer 34 on the basis of a method described below. At present, adhesion to a base becomes higher in order of a material for forming the blue color filter layer 51B, a material for forming the red color filter layer 51R, and a material for forming the green color filter layer 51G.

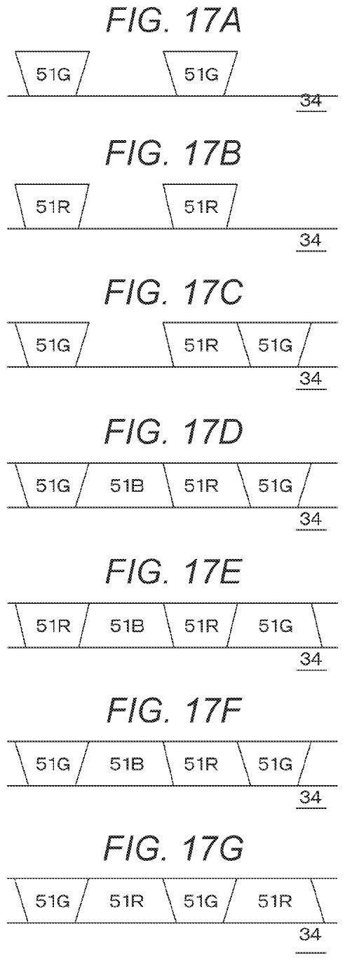

Therefore, first, the green color filter layer 51G having the highest adhesion is formed on the protective layer 34. Specifically, a photosensitive material constituting the green color filter layer 51G is applied to the entire surface, and the resulting product is subjected to exposure, baking, and development to form the green color filter layer 51G having a desired pattern shape. Note that as illustrated in FIG. 17A, the cross-section of the green color filter layer 51G obtained by application of a photosensitive material, exposure, baking, and development during formation of the green color filter layer 51G has a side surface having a reverse taper shape.

Subsequently, a photosensitive material constituting red color filter layer 51R is applied to the entire surface, and the resulting product is subjected to exposure, baking, and development to form the red color filter layer 51R having a desired pattern shape. Note that as illustrated in FIG. 17B, the cross-section of the red color filter layer 51R obtained by application of a photosensitive material, exposure, baking, and development during formation of the red color filter layer 51R has a side surface having a reverse taper shape in a case where the red color filter layer 51R is not in contact with the green color filter layer 51G. Furthermore, as illustrated in FIG. 17C, in a case where one side of the red color filter layer 51R is in contact with the green color filter layer 51G, one side surface has a reverse taper shape and the other side surface has a forward taper shape. Moreover, as illustrated in FIG. 17G, in a case where both sides of the red color filter layer 51R are in contact with the green color filter layer 51G, both side surfaces have forward taper shapes.

Finally, a photosensitive material constituting blue color filter layer 51B is applied to the entire surface, and the resulting product is subjected to exposure, baking, and development to form the blue color filter layer 51B having a desired pattern shape. Note that the blue color filter layer 51B is formed in a region where the green color filter layer 51G or the red color filter layer 51R is not formed. As illustrated in FIG. 17D, 17E, or 17F, the cross-section of the blue color filter layer 51B obtained by application of a photosensitive material, exposure, baking, and development during formation of the blue color filter layer 51B has a side surface having a forward taper shape.

In the display device of the first embodiment, the cross-sectional shapes of the green color filter layer 51G, the red color filter layer 51R, and the blue color filter layer 51B are the cross-sectional shapes illustrated in FIG. 17F (see (B) of FIG. 1 and (B) of FIG. 2).

Here, as described above, in adjacent light emitting elements, an angle (θ) formed by the shortest line segment (see also the dotted line in FIG. 4) connecting a boundary line (see also the reference numerals 52₁, 52₂, and 52₃ in FIG. 4) of a bottom surface of the color filter layer 51R, 51G, 51B facing the light emitting region 11R, 11G, 11B and an end (see also the reference numerals 11R_{R}, 11R_{L}, 11G_{R}, 11G_{L}, 11B_{R}, and 11B_{L} in FIG. 4) of the light emitting region 11R, 11G, 11B with a normal line of the base body 26 (or the first substrate 41 or the second substrate 42) is the same in the light emitting elements 10R, 10G, and 10B.

Furthermore, a distance (L) from an orthogonal projection image (see also the alternate long and short dash line in FIG. 4) of a boundary line (see also the reference numerals 52₁, 52₂, and 52₃ in FIG. 4) of a bottom surface of the color filter layer 51R, 51G, 51B facing the light emitting region 11R, 11G, 11B onto the base body 26 (or the first substrate 41 or the second substrate 42) to an orthogonal projection image (see also the alternate long and short dash line in FIG. 4) of an end of the light emitting region 11R, 11G, 11B onto the base body 26 (or the first substrate 41 or the second substrate 42) is the same in the light emitting elements 10R, 10G, and 10B.

As schematically illustrated in FIG. 4, when white light emitted from the right end 11G_{R} of the second light emitting region 11G enters the blue color filter layer 51B on the right side in FIG. 4 with respect to the boundary line 52₁ of a bottom surface between the green color filter layer 51G and the blue color filter layer 51B (see the arrow G₁ in FIG. 4), a sub-pixel that originally displays green displays blue. Similarly, when white light emitted from the right end 11B_{R} of the third light emitting region 11B enters the red color filter layer 51R on the right side in FIG. 4 with respect to the boundary line 52₂ of a bottom surface between the blue color filter layer 51B and the red color filter layer 51R (see the arrow B₁ in FIG. 4), a sub-pixel that originally displays blue displays red. Similarly, when white light emitted from the right end 11R_{R} of the first light emitting region 11R enters the green color filter layer 51G on the right side in FIG. 4 with respect to the boundary line 52₃ of a bottom surface between the red color filter layer 51R and the green color filter layer 51G (see the arrow R₁ in FIG. 4), a sub-pixel that originally displays red displays green.

Furthermore, when white light emitted from the left end 11B_{L} of the third light emitting region 11B enters the green color filter layer 51G on the left side in FIG. 4 with respect to the boundary line 52₁ (see the arrow B₂ in FIG. 4), a sub-pixel that originally displays blue displays green. Similarly, when white light emitted from the left end 11R_{L} of the first light emitting region 11R enters the blue color filter layer 51B on the left side in FIG. 4 with respect to the boundary line 52₂ (see the arrow R₂ in FIG. 4), a sub-pixel that originally displays red displays blue. Similarly, when white light emitted from the left end 11G_{L} of the second light emitting region 11G enters the red color filter layer 51R on the left side in FIG. 4 with respect to the boundary line 52₃ (see the arrow G₂ in FIG. 4), a sub-pixel that originally displays green displays red.

In this way, for example, when a certain pixel is viewed from the diagonal upper right illustrated by “A” in FIG. 4, color mixing and color shift occur, but an angle Θ when color mixing and color shift start to occur is the same in the red light emitting element 10R, the green light emitting element 10G, and the blue light emitting element 10B. For example, in a case where a certain pixel displays white, the angle Θ when color mixing and color shift start to occur is the same in the light emitting elements. Therefore, even when the certain pixel is viewed at an oblique angle larger than the angle Θ, the pixel is observed as a white display, and therefore color mixing and color shift do not occur.

In a case where the angle (θ) is different among the light emitting elements, for example, in a case where the angle (θ) in the green light emitting element is smaller than the angle (θ) in each of the red light emitting element and the blue light emitting element, for example, when a certain pixel displays white, in a case where the angle Θ when color mixing and color shift start to occur is the smallest in the green light emitting element, when this certain pixel is viewed at an oblique angle larger than the angle Θ_{G}, a pixel that originally looks white is observed as greenish, and color mixing and color shift occur.

As described above, in the display device according to the first embodiment or the various embodiments described later, in adjacent light emitting element, an angle (θ) formed by the shortest line segment connecting a boundary line of a bottom surface of the color filter layer and an end of the light emitting region with a normal line of the base body (or a first substrate or a second substrate described later) is the same in the light emitting elements, and a distance (L) from an orthogonal projection image of a boundary line of a bottom surface of the color filter layer onto the base body (or the first substrate or the second substrate described later) to an orthogonal projection image of an end of the light emitting region onto the base body (or the first substrate or the second substrate described later) is the same in the light emitting elements. Therefore, as a result of being able to reduce a difference in behavior of light emitted from a certain light emitting region and entering a color filter layer constituting an adjacent light emitting element among the light emitting elements, color shift and color mixing are unlikely to occur.

In the first embodiment, the organic layer 33 has a laminated structure of a hole injection layer (HIL), a hole transport layer (HTL), a light emitting layer, an electron transport layer (ETL), and an electron injection layer (EIL). The light emitting layer is constituted by at least two light emitting layers that emit different colors, and light emitted from the organic layer 33 is white. Specifically, the light emitting layer has a structure in which three layers of a red light emitting layer that emits red light, a green light emitting layer that emits green light, and a blue light emitting layer that emits blue light are laminated. The light emitting layer may have a structure in which two layers of a blue light emitting layer that emits blue light and a yellow light emitting layer that emits yellow light are laminated or a structure in which two layers of a blue light emitting layer that emits blue light and an orange light emitting layer that emits orange light are laminated. As described above, the red light emitting element 10R to display a red color includes the red color filter layer 51R. The green light emitting element 10G to display a green color includes the green color filter layer 51G. The blue light emitting element 10B to display a blue color includes the blue color filter layer 51B. The red light emitting element 10R, the green light emitting element 10G, and the blue light emitting element 10B have the same configuration and structure except for a positional relationship between the color filter layer 51R, 51G, 51B and the light emitting region 11R, 11G, 11B.

The hole injection layer increases a hole injection efficiency, functions as a buffer layer for preventing leakage, and has a thickness of about 2 nm to 10 nm, for example. The hole injection layer includes a hexaazatriphenylene derivative represented by the following formula (A) or (B), for example. Note that contact of an end face of the hole injection layer with the second electrode becomes a main cause of occurrence of brightness variation among pixels, leading to deterioration in display image quality.

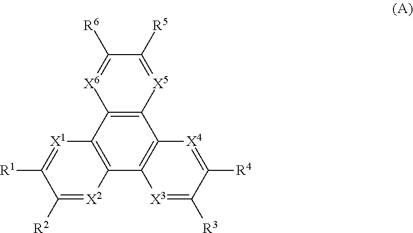

Here, R¹ to R⁶ each independently represent a substituent selected from a hydrogen atom, a halogen atom, a hydroxy group, an amino group, an arulamino group, a substituted or unsubstituted carbonyl group having 20 or less carbon atoms, a substituted or unsubstituted carbonyl ester group having 20 or less carbon atoms, a substituted or unsubstituted alkyl group having 20 or less carbon atoms, a substituted or unsubstituted alkenyl group having 20 or less carbon atoms, a substituted or unsubstituted alkoxy group having 20 or less carbon atoms, a substituted or unsubstituted aryl group having 30 or less carbon atoms, a substituted or unsubstituted heterocyclic group having 30 or less carbon atoms, a nitrile group, a cyano group, a nitro group, and a silyl group, and adjacent R^{m}s (m=1 to 6) may be bonded to each other via a cyclic structure. Furthermore, X¹ to X⁶ each independently represent a carbon atom or a nitrogen atom.

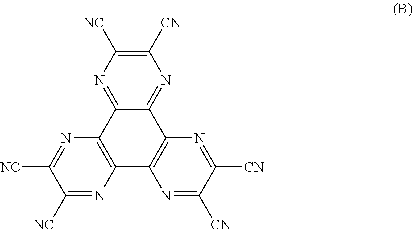 [SMILES: N#Cc1nc2c3nc(C#N)c(C#N)nc3c3nc(C#N)c(C#N)nc3c2nc1C#N]

The hole transport layer is a layer that increases a hole transport efficiency to the light emitting layer. When an electric field is applied to the light emitting layer, recombination of electrons and holes occurs to generate light. The electron transport layer is a layer that increases an electron transport efficiency to the light emitting layer, and the electron injection layer is a layer that increases an electron injection efficiency to the light emitting layer.

The hole transport layer includes 4,4′,4″-tris(3-methylphenylphenylamino) triphenylamine (m-MTDATA) or α-naphthylphenyl diamine (αNPD) having a thickness of about 40 nm, for example.

The light emitting layer is a light emitting layer that generates white light by color mixing, and is formed by laminating a red light emitting layer, a green light emitting layer, and a blue light emitting layer as described above, for example.

In the red light emitting layer, by application of an electric field, a part of holes injected from the first electrode 31 and a part of electrons injected from the second electrode 32 are recombined to generate red light. Such a red light emitting layer contains at least one kind of material among a red light emitting material, a hole transport material, an electron transport material, and a both charge transport material, for example. The red light emitting material may be a fluorescent material or a phosphorescent material. The red light emitting layer having a thickness of about 5 nm is formed by mixing 30% by mass of 2,6-bis[(4′-methoxydiphenylamino) styryl]-1,5-dicyanonaphthalene (BSN) with 4,4-bis(2,2-diphenylvinyl) biphenyl (DPVBi), for example.

In the green light emitting layer, by application of an electric field, a part of holes injected from the first electrode 31 and a part of electrons injected from the second electrode 32 are recombined to generate green light. Such a green light emitting layer contains at least one kind of material among a green light emitting material, a hole transport material, an electron transport material, and a both charge transport material, for example. The green light emitting material may be a fluorescent material or a phosphorescent material. The green light emitting layer having a thickness of about 10 nm is formed by mixing 5% by mass of coumarin 6 with DPVBi, for example.

In the blue light emitting layer, by application of an electric field, a part of holes injected from the first electrode 31 and a part of electrons injected from the second electrode 32 are recombined to generate blue light. Such a blue light emitting layer contains at least one kind of material among a blue light emitting material, a hole transport material, an electron transport material, and a both charge transport material, for example. The blue light emitting material may be a fluorescent material or a phosphorescent material. The blue light emitting layer having a thickness of about 30 nm is formed by mixing 2.5% by mass of 4,4′-bis[2-{4-(N,N-diphenylamino) phenyl} vinyl] biphenyl (DPAVBi) with DPVBi, for example.

The electron transport layer having a thickness of about 20 nm includes 8-hydroxyquinoline aluminum (Alq3), for example. The electron injection layer having a thickness of about 0.3 nm includes LiF, Li₂O, or the like, for example.

However, the materials constituting the layers are illustrative, and are not limited to these materials. Furthermore, for example, the light emitting layer may be constituted by a blue light emitting layer and a yellow light emitting layer, or may be constituted by a blue light emitting layer and an orange light emitting layer.

The light emitting element 10R, 10G, 10B has a resonator structure using the organic layer 33 as a resonance part. Note that the thickness of the organic layer 33 is preferably 8×10−8m or more and 5×10^{-7m} or less, and more preferably 1.5×10^{-7m} or more and 3.5×10^{-7m} or less in order to appropriately adjust a distance from a light emitting surface to a reflecting surface (specifically, a distance from a light emitting surface to each of the first electrode 31 and the second electrode 32). In an organic EL display device having a resonator structure, actually, the red light emitting element 10R causes red light emitted from the light emitting layer to resonate, and emits reddish light (light having a light spectrum peak in a red region) from the second electrode 32. Furthermore, the green light emitting element 10G causes green light emitted from the light emitting layer to resonate, and emits greenish light (light having a light spectrum peak in a green region) from the second electrode 32. Furthermore, the blue light emitting element 10B causes blue light emitted from the light emitting layer to resonate, and emits bluish light (light having a light spectrum peak in a blue region) from the second electrode 32.

Hereinafter, an outline of a method for manufacturing the light emitting element of the first embodiment illustrated in FIG. 18 will be described.

### [Step-100]

First, a light emitting element driving unit is formed on a silicon semiconductor substrate (first substrate 41) on the basis of a known MOSFET manufacturing process.

### [Step-110]

Subsequently, the base body 26 is formed on the entire surface on the basis of a CVD method.

### [Step-120]

Next, in a portion of the base body 26 positioned above one of source/drain regions of the transistor 20, a connection hole is formed on the basis of a photolithography technique and an etching technique. Thereafter, a metal layer is formed on the base body 26 including the connection hole, for example, on the basis of a sputtering method. Subsequently, the metal layer is patterned on the basis of the photolithography technique and the etching technique, and the first electrode 31 can be thereby formed on the base body 26. The first electrode 31 is isolated for each of the light emitting elements. At the same time, the contact hole (contact plug) 27 for electrically connecting the first electrode 31 to the transistor 20 can be formed in the connection hole.

### [Step-130]

Next, the insulating layer 28 is formed on the entire surface, for example, on the basis of a CVD method. Thereafter, the opening 29 is formed in a part of the insulating layer 28 on the first electrode 31 on the basis of the photolithography technique and the etching technique. The first electrode 31 is exposed to a bottom of the opening 29.

### [Step-140]

Thereafter, a film of the organic layer 33 is formed on the first electrode 31 and the insulating layer 28 by a PVD method such as a vacuum vapor deposition method or a sputtering method, or a coating method such as a spin coating method or a die coating method, for example. Subsequently, the second electrode 32 is formed on the entire surface on the basis of a vacuum vapor deposition method or the like, for example. In this way, the organic layer 33 and the second electrode 32 can be formed on the first electrode 31.

### [Step-150]

Thereafter, the protective layer 34 is formed on the entire surface, for example, by a CVD method or a PVD method. Then, as described above, the color filter layer 51R, 51G, 51B is formed on the protective layer 34. Finally, the second substrate 42 and the color filter layer 51R, 51G, 51B are bonded to each other via the resin layer (sealing resin layer) 35. In this way, the organic EL display device illustrated in FIG. 18 can be obtained.

### Second Embodiment

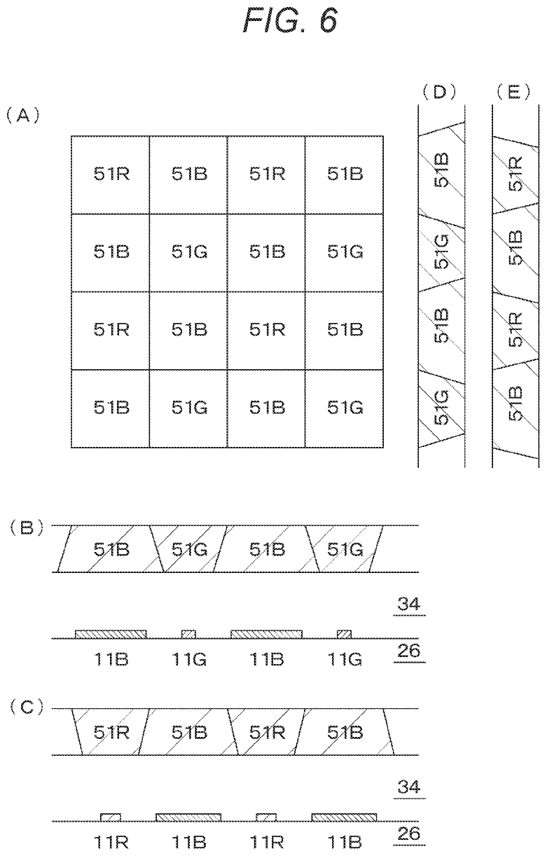

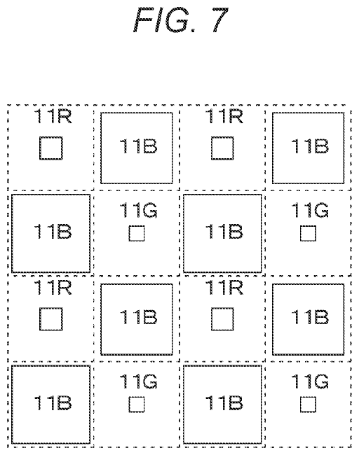

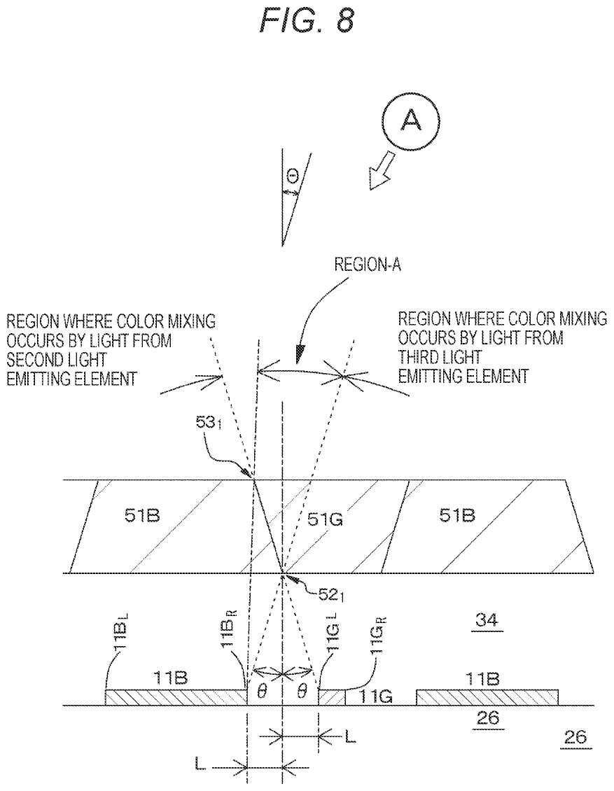

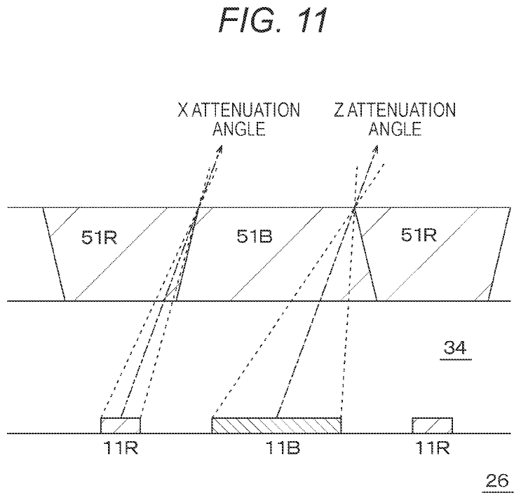

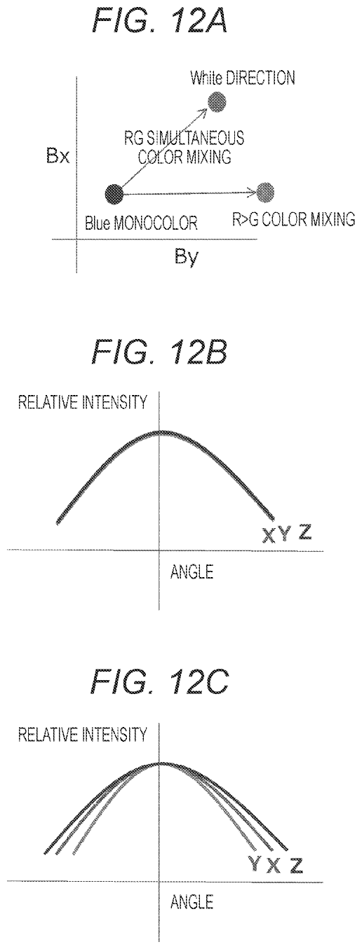

The second embodiment is a modification of the first embodiment. An arrangement of color filter layers in the display device of the second embodiment is schematically illustrated in (A) of FIG. 5 and (A) of FIG. 6. A conceptual cross-sectional view of the display device of the second embodiment along the arrow B-B in (A) of FIG. 5 is illustrated in (B) of FIG. 5 and (B) of FIG. 6. A conceptual cross-sectional view of the display device of the second embodiment along the arrow C-C in (A) of FIG. 5 is illustrated in (C) of FIG. 5 and (C) of FIG. 6. A conceptual cross-sectional view of the display device of the second embodiment along the arrow D-D in (A) of FIG. 5 is illustrated in (D) of FIG. 5 and (D) of FIG. 6. A conceptual cross-sectional view of the display device of the second embodiment along the arrow E-E in (A) of FIG. 5 is illustrated in (E) of FIG. 5 and (E) of FIG. 6. An arrangement of light emitting regions in the display device of the second embodiment is schematically illustrated in FIG. 7. Furthermore, a conceptual cross-sectional view of the display device of the second embodiment for explaining that color mixing is unlikely to occur in the display device of the second embodiment is illustrated in FIGS. 8, 9, 10, and 11. A mechanism by which color mixing occurs in the display device of the second embodiment and a conventional display device is illustrated in FIGS. 12A, 12B, and 12C.

In the display device of the second embodiment, the light emitting element group is constituted by four light emitting elements arranged in 2×2,

the first light emitting element 10R is arranged adjacent to the two third light emitting elements 10B,

the second light emitting element 10G is arranged adjacent to the two third light emitting elements 10B, and

each of the two third light emitting elements 10B is arranged adjacent to the first light emitting element 10R and the second light emitting element 10G. That is, in the display device of the second embodiment, the light emitting elements are arranged in a form of diagonal arrangement. That is, an arrangement of sub-pixels is a diagonal arrangement. The light emitting element group occupies, for example, a rectangular region.

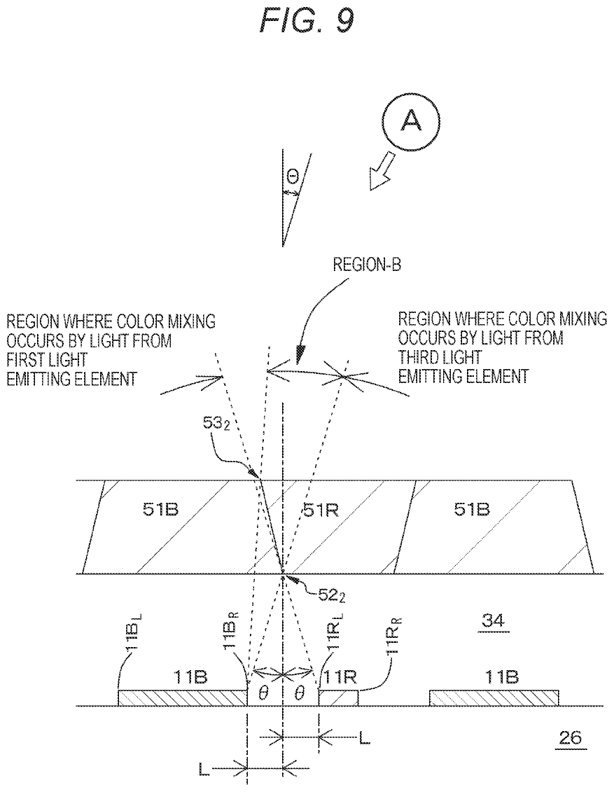

As illustrated in (B) and (C) of FIG. 5, and FIGS. 8 and 9, in the second embodiment as well as in the first embodiment, in adjacent light emitting elements, an angle (θ) formed by the shortest line segment (indicated by dotted lines in (B) of FIG. 5 and FIGS. 8 and 9) connecting a boundary line 52₁, 52₂ of a bottom surface of the color filter layer 51R, 51G, 51B facing the light emitting region 11R, 11G, 11B and an end 11B_{R}, 11G_{L}, 11B_{R}, 11R_{L} of the light emitting region 11R, 11G, 11B with a normal line of the base body 26 (or the first substrate 41 or the second substrate 42) is the same in the light emitting elements 10R, 10G, and 10B. Furthermore, in adjacent light emitting elements, a distance (L) from an orthogonal projection image of the boundary line 52₁, 52₂ of a bottom surface of the color filter layer 51R, 51G, 51B facing the light emitting region 11R, 11G, 11B onto the base body 26 (or the first substrate 41 or the second substrate 42) to an orthogonal projection image of the end 11B_{R}, 11G_{L}, 11B_{R}, 11R_{L} of the light emitting region 11R, 11G, 11B onto the base body 26 (or the first substrate 41 or the second substrate 42) is the same in the light emitting elements 10R, 10G, and 10B. Note that in (B) of FIG. 5 and FIGS. 8 and 9, these orthogonal projection images are indicated by alternate long and short dash lines.

In the display device of the second embodiment, the cross-sectional shapes of the green color filter layer 51G, the red color filter layer 51R, and the blue color filter layer 51B are the cross-sectional shapes illustrated in FIGS. 17D and 17E (see (B) and (C) of FIG. 5, (B) and (C) of FIG. 6, and FIGS. 8 and 9).

The configuration and structure of the display device of the second embodiment can be similar to those of the display device described in the first embodiment except for the above-described points, and therefore detailed description thereof will be omitted.

As schematically illustrated in FIG. 8, when white light emitted from the right end 11B_{R} of the third light emitting region 11B enters the green color filter layer 51G on the right side in FIG. 8 with respect to the boundary line 52₁ of a bottom surface between the blue color filter layer 51B and the green color filter layer 51G, a sub-pixel that originally displays blue displays green. In FIG. 8, this region is displayed as “a region where color mixing occurs by light from the third light emitting region”. Note that when white light emitted from the right end 11B_{R} of the third light emitting region 11B enters the green color filter layer 51G on the right side in FIG. 8 with respect to the boundary line 53₁ of a top surface between the blue color filter layer 51B and the green color filter layer 51G, blue light from a sub-pixel that originally displays blue is absorbed by the green color filter layer 51G, and therefore is not emitted from the green color filter layer 51G. In FIG. 8, this region is indicated by “region-A”.

Furthermore, when white light emitted from the left end 11G_{L} of the second light emitting region 11G enters the blue color filter layer 51B on the left side in FIG. 8 with respect to the boundary line 52₁, a sub-pixel that originally displays green displays blue. In FIG. 8, this region is displayed as “a region where color mixing occurs by light from the second light emitting region”.

Similarly, as schematically illustrated in FIG. 9, when white light emitted from the right end 11B_{R} of the third light emitting region 11B enters the red color filter layer 51R on the right side in FIG. 9 with respect to the boundary line 52₂ of a bottom surface between the blue color filter layer 51B and the red color filter layer 51R, a sub-pixel that originally displays blue displays red. In FIG. 8, this region is displayed as “a region where color mixing occurs by light from the third light emitting region”. Note that when white light emitted from the right end 11B_{R} of the third light emitting region 11B enters the red color filter layer 51R on the right side in FIG. 8 with respect to the boundary line 53₂ of a top surface between the blue color filter layer 51B and the red color filter layer 51R, blue light from a sub-pixel that originally displays blue is absorbed by the red color filter layer 51R, and therefore is not emitted from the red color filter layer 51R. In FIG. 8, this region is indicated by “region-B”.

Furthermore, when white light emitted from the left end 11R_{L} of the first light emitting region 11R enters the blue color filter layer 51B on the left side in FIG. 9 with respect to the boundary line 52₁, a sub-pixel that originally displays red displays blue. In FIG. 9, this region is displayed as “a region where color mixing occurs by light from the first light emitting region”.

In this way, for example, when a certain pixel is viewed from the diagonal upper left illustrated by “A” in FIGS. 8 and 9, color mixing and color shift occur, but an angle Θ when color mixing and color shift start to occur is the same in the red light emitting element 10R and the green light emitting element 10G. For example, in a case where a certain pixel displays white, the angle Θ when color mixing and color shift start to occur is the same in the light emitting elements. Therefore, even when the certain pixel is viewed at an oblique angle larger than the angle Θ, the pixel is observed as a white display, and therefore color mixing and color shift do not occur (see FIG. 12A). In addition, color mixing can be prevented. Therefore, color purity increases when monochromatic light is emitted from a pixel, and a chromaticity point is deep. Therefore, a color gamut is widened, and a range of color expression of the display device is widened.

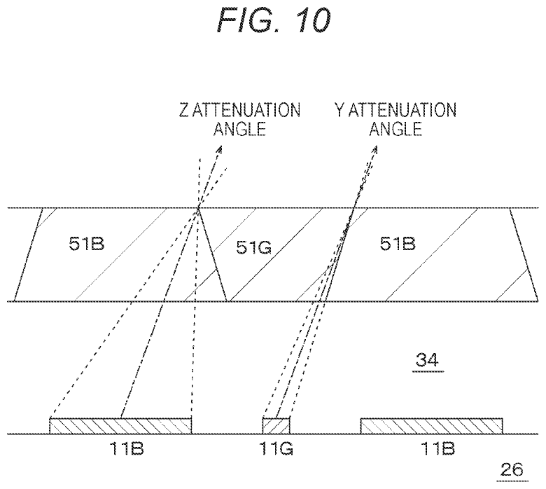

A Z attenuation angle and a Y attenuation angle when white light emitted from the third light emitting region 11B and white light emitted from the second light emitting region 11G pass through the blue color filter layer 51B and the green color filter layer 51G, respectively, are illustrated in FIG. 10. Furthermore, a Z attenuation angle and an X attenuation angle when white light emitted from the third light emitting region 11B and white light emitted from the first light emitting region 11R pass through the blue color filter layer 51B and the red color filter layer 51R, respectively, are illustrated. Moreover, a relationship between a viewing angle and relative intensities of X, Y, and Z is schematically illustrated in FIG. 12B, but in the display device of the second embodiment, changes in the relative intensities of X, Y, and Z are the same as each other, and color mixing and color shift do not occur.

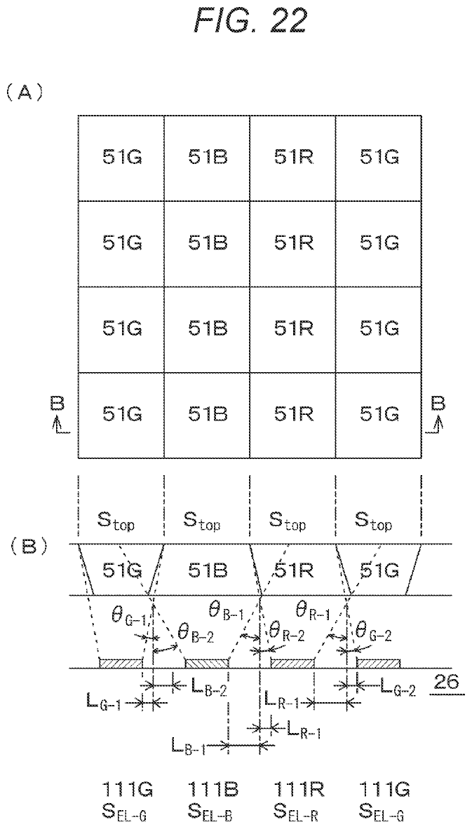

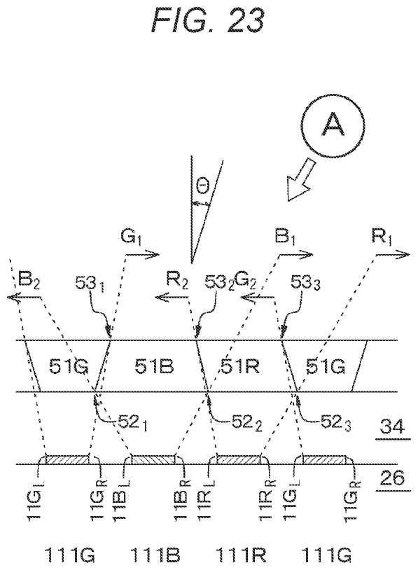

An arrangement of color filter layers in a conventional display device is schematically illustrated in (A) of FIG. 22, and a conceptual cross-sectional view of the conventional display device along the arrow B-B in (A) of FIG. 22 is illustrated in (B) of FIG. 22. Furthermore, various conceptual cross-sectional views of the conventional display device for explaining that color mixing occurs in the conventional display device are illustrated in FIG. 23. In the conventional display device, the area (Sₜₒₚ) of an orthogonal projection image of a top surface region of the color filter layer 51R, 51G, 51B surrounded by a boundary line between a top surface of a color filter layer (light emitting surface) and a top surface of a color filter layer (light emitting surface) onto the base body 26 (or the first substrate 41 or the second substrate 42) is the same in the first light emitting element, the second light emitting element, and the third light emitting element. Furthermore, the areas of the light emitting regions 111R, 111G, and 111B are also the same as each other. Therefore, inevitably, an angle (θ_{R-1}, θ_{R-2}, θ_{G-1}, θ_{G-2}, θ_{B-1}, θ_{B-2}) formed by the shortest line segment connecting a boundary line of a bottom surface of the color filter layer 51R, 51G, 51B facing the light emitting region 111R, 111G, 111B and an end of the light emitting region 111R, 111G, 111B with a normal line of the base body 26 (or the first substrate 41 or the second substrate 42) is different among the light emitting elements, and in adjacent light emitting elements, a distance (L_{R-1}, L_{R-2}, L_{G-1}, L_{G-2}, L_{B-1}, L_{B-2}) from an orthogonal projection image of a boundary line of a bottom surface of the color filter layer 51R, 51G, 51B facing the light emitting region 111R, 111G, 111B onto the base body 26 (or the first substrate 41 or the second substrate 42) to an orthogonal projection image of an end of the light emitting region onto the base body (or the first substrate 41 or the second substrate 42) is different among the light emitting elements.

As schematically illustrated in FIG. 23, when white light emitted from the right end 11G_{R} of the second light emitting region 11G enters the blue color filter layer 51B on the right side in FIG. 23 with respect to the boundary line 52₁ of a bottom surface between the green color filter layer 51G and the blue color filter layer 51B (see the arrow G₁ in FIG. 23), a sub-pixel that originally displays green displays blue. Similarly, when white light emitted from the right end 11B_{R} of the third light emitting region 11B enters the red color filter layer 51R on the right side in FIG. 23 with respect to the boundary line 52₂ of a bottom surface between the blue color filter layer 51B and the red color filter layer 51R (see the arrow B₁ in FIG. 23), a sub-pixel that originally displays blue displays red. Similarly, when white light emitted from the right end 11R_{R} of the first light emitting region 11R enters the green color filter layer 51G on the right side in FIG. 23 with respect to the boundary line 52₃ of a bottom surface between the red color filter layer 51R and the green color filter layer 51G (see the arrow R₁ in FIG. 23), a sub-pixel that originally displays red displays green.

Furthermore, when white light emitted from the left end 11B_{L} of the third light emitting region 11B enters the green color filter layer 51G on the left side in FIG. 23 with respect to the boundary line 52₁ (see the arrow B₂ in FIG. 23), a sub-pixel that originally displays blue displays green. Similarly, when white light emitted from the left end 11R_{L} of the first light emitting region 11R enters the blue color filter layer 51B on the left side in FIG. 23 with respect to the boundary line 52₂ (see the arrow R₂ in FIG. 23), a sub-pixel that originally displays red displays blue. Similarly, when white light emitted from the left end 11G_{L} of the second light emitting region 11G enters the red color filter layer 51R on the left side in FIG. 23 with respect to the boundary line 52₂ (see the arrow G₂ in FIG. 23), a sub-pixel that originally displays green displays red.

In this way, for example, when a certain pixel is viewed from the diagonal upper right illustrated by “A” in FIG. 23, color mixing and color shift occur, but an angle Θ when color mixing and color shift start to occur is different among the red light emitting element 10R, the green light emitting element 10G, and the blue light emitting element 10B. For example, in a case where a certain pixel displays white, the angle G when color mixing and color shift start to occur is the smallest in the green light emitting element 10G. Therefore, when this certain pixel is viewed at an oblique angle larger than the angle Θ, a pixel that looks white is observed as greenish, and color mixing and color shift occur (see FIGS. 12A and 12C).

### Third Embodiment

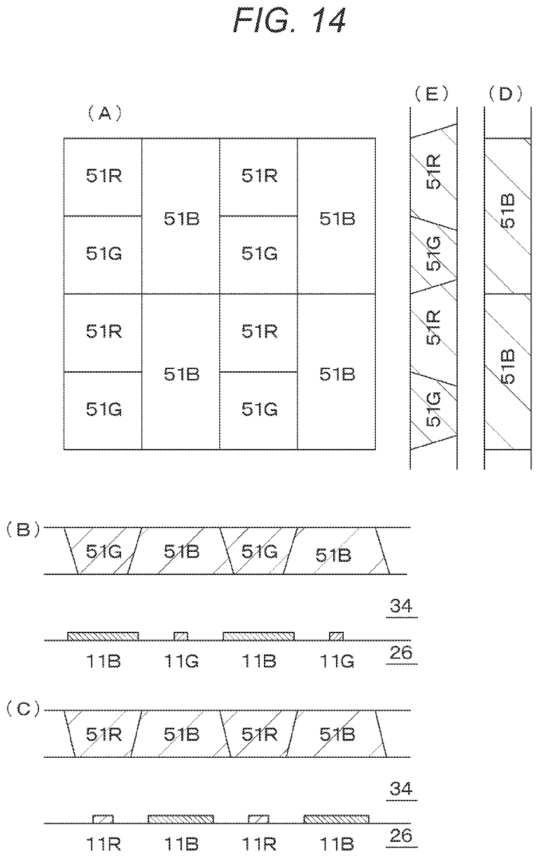

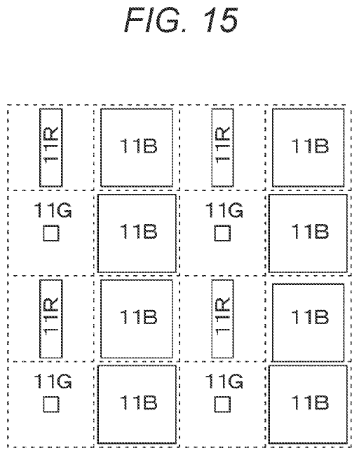

The third embodiment is a modification of the first embodiment. An arrangement of color filter layers in the display device of the third embodiment is schematically illustrated in (A) of FIG. 13 and (A) of FIG. 14. A conceptual cross-sectional view of the display device of the third embodiment as in the view along the arrow B-B in (A) of FIG. 5 is illustrated in (B) of FIG. 13 and (B) of FIG. 14. A conceptual cross-sectional view of the display device of the third embodiment as in the view along the arrow C-C in (A) of FIG. 5 is illustrated in (C) of FIG. 13 and (C) of FIG. 14. A conceptual cross-sectional view of the display device of the third embodiment as in the view along the arrow D-D in (A) of FIG. 5 is illustrated in (D) of FIG. 13 and (D) of FIG. 14. A conceptual cross-sectional view of the display device of the third embodiment as in the view along the arrow E-E in (A) of FIG. 5 is illustrated in (E) of FIG. 13 and (E) of FIG. 14. An arrangement of light emitting regions in the display device of the third embodiment is schematically illustrated in FIG. 15.

In the display device of the third embodiment, the light emitting element group is constituted by the one first light emitting element 10R, the one second light emitting element 10G, and the one third light emitting element 10B,

the first light emitting element 10R is arranged adjacent to the second light emitting element 10G and the third light emitting element 10B, and

the second light emitting element 10G is arranged adjacent to the first light emitting element 10R and the third light emitting element 10B. Note that the light emitting element group occupies, for example, a rectangular region.

As illustrated in (B), (C), and (E) of FIG. 13, in the third embodiment as well as in the first embodiment, in adjacent light emitting elements, an angle (θ) formed by the shortest line segment (indicated by dotted lines in (B) of FIG. 13) connecting a boundary line of a bottom surface of the color filter layer 51R, 51G, 51B facing the light emitting region 11R, 11G, 11B and an end of the light emitting region 11R, 11G, 11B with a normal line of the base body 26 (or the first substrate 41 or the second substrate 42) is the same in the light emitting elements 10R, 10G, and 10B. Furthermore, in adjacent light emitting elements, a distance (L) from an orthogonal projection image of a boundary line of a bottom surface of the color filter layer 51R, 51G, 51B facing the light emitting region 11R, 11G, 11B onto the base body 26 (or the first substrate 41 or the second substrate 42) to an orthogonal projection image of an end of the light emitting region 11R, 11G, 11B onto the base body 26 (or the first substrate 41 or the second substrate 42) is the same in the light emitting elements 10R, 10G, and 10B. Note that in (B), (C), and (E) of FIG. 13, these orthogonal projection images are indicated by alternate long and short dash lines.

In the display device of the third embodiment, the cross-sectional shapes of the green color filter layer 51G, the red color filter layer 51R, and the blue color filter layer 51B are the cross-sectional shapes illustrated in FIGS. 17D, 17E, and 17G (see (B) and (C) of FIG. 13 and (B) of FIG. 14).

Since the discussion on color mixing and color shift in each of the light emitting elements in the third embodiment is basically similar to the discussion on color mixing and color shift in each of the light emitting elements in the second embodiment, detailed description thereof will be omitted. Furthermore, the configuration and structure of the display device of the third embodiment can be similar to those of the display device described in the second embodiment except for the above-described points, and therefore detailed description thereof will be omitted.

### Fourth Embodiment

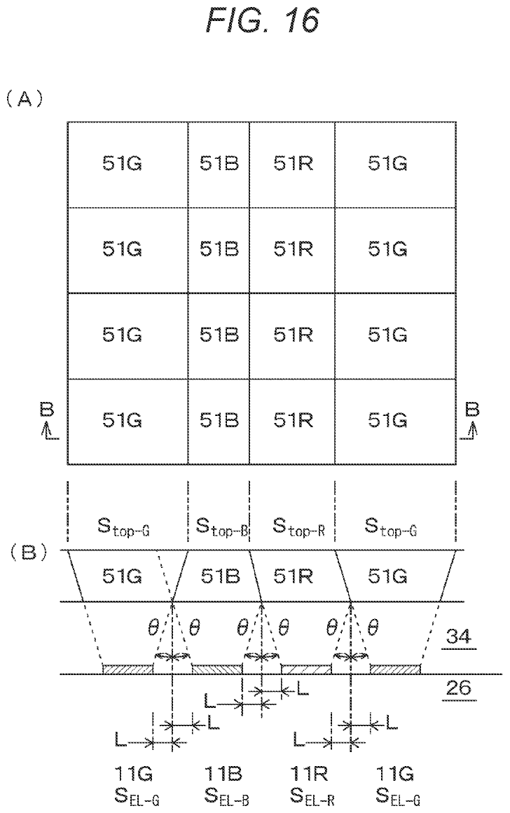

The fourth embodiment is a modification of the first embodiment. An arrangement of color filter layers in the display device of the fourth embodiment is schematically illustrated in (A) of FIG. 16, and a conceptual cross-sectional view of the display device of the fourth embodiment along the arrow B-B in (A) of FIG. 16 is illustrated in (B) of FIG. 16.

In the display device of the fourth embodiment, the area (S_{top-R}, S_{top-G}, S_{top-B}) of an orthogonal projection image of a top surface region of the color filter layer 51R, 51G, 51B surrounded by a boundary line between a top surface of a color filter layer (light emitting surface) and a top surface of a color filter layer (light emitting surface) onto the base body 26 (or the first substrate 41 or the second substrate 42) is different among the first light emitting element 10R, the second light emitting element 10G, and the third light emitting element 10B. The area (S_{EL-R}, S_{EL-G}, S_{EL-B}) of the light emitting region 11R, 11G, 11B is the same in the first light emitting element 10R, the second light emitting element 10G, and the third light emitting element 10B.

As illustrated in (B) of FIG. 16, in the fourth embodiment as well as in the first embodiment, in adjacent light emitting elements 10R, 10G, and 10B, an angle (θ) formed by the shortest line segment (indicated by dotted lines in (B) of FIG. 16) connecting a boundary line of a bottom surface of the color filter layer 51R, 51G, 51B facing the light emitting region 11R, 11G, 11B and an end of the light emitting region 11R, 11G, 11B with a normal line of the base body 26 (or the first substrate 41 or the second substrate 42) is the same in the light emitting elements 10R, 10G, and 10B. Furthermore, in adjacent light emitting elements, a distance (L) from an orthogonal projection image of a boundary line of a bottom surface of the color filter layer 51R, 51G, 51B facing the light emitting region 11R, 11G, 11B onto the base body 26 (or the first substrate 41 or the second substrate 42) to an orthogonal projection image of an end of the light emitting region 11R, 11G, 11B onto the base body 26 (or the first substrate 41 or the second substrate 42) is the same in the light emitting elements 10R, 10G, and 10B. Note that in (B) of FIG. 16, these orthogonal projection images are indicated by alternate long and short dash lines.

Furthermore, in a case where the center of a top surface region of the color filter layer 51R, 51G, 51B surrounded by a boundary line between a top surface of a color filter layer (light emitting surface) and a top surface of a color filter layer (light emitting surface), and the center of the light emitting region 11R, 11G, 11B are viewed from a normal line direction of the base body, these centers do not overlap with each other.

Since the discussion on color mixing and color shift in each of the light emitting elements in the fourth embodiment is basically similar to the discussion on color mixing and color shift in each of the light emitting elements in the first embodiment, detailed description thereof will be omitted. Furthermore, the configuration and structure of the display device of the fourth embodiment can be similar to those of the display device described in the first embodiment except for the above-described points, and therefore detailed description thereof will be omitted. Note that it goes without saying that the configuration and structure of the display device of the fourth embodiment can be applied to the display devices described in the second and third embodiments.

Hitherto, the present disclosure has been described on the basis of the preferable embodiments. However, the present disclosure is not limited to these embodiments. The configurations and structures of the display device (organic EL display device) and the light emitting element (organic EL element) described in the embodiments are illustrative and can be changed appropriately. The method for manufacturing the display device is also illustrative and can be changed appropriately. In the embodiments, one pixel is constituted exclusively by three sub-pixels formed by a combination of a white light emitting element and a color filter layer. However, for example, one pixel may be formed by four sub-pixels obtained by adding a light emitting element that emits white light. In this case, it is only required for the three light emitting elements other than the light emitting element that emits white light to satisfy the requirements of the display devices according to the first and second aspects of the present disclosure.

Alternatively, the first light emitting region 11R may emit red light, the second light emitting region 11G may emit green light, and the third light emitting region 11B may emit blue light. That is, as the light emitting element, a light emitting element in which an organic layer generates red, a light emitting element in which an organic layer generates green, and a light emitting element in which an organic layer generates blue may be used, and one pixel may be formed by combining these three kinds of light emitting elements (sub-pixels). Even in a display device having such a configuration, a color filter layer is disposed for the purpose of improving color purity and the like, and therefore color mixing and color shift may occur.

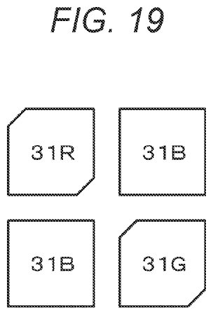

As FIG. 19 schematically illustrates an arrangement of the light emitting regions 11R, 11G, and 11B as a modification in the display device of the second embodiment, the planar shape of each of the first light emitting region 11R and the second light emitting region 11G may also be a shape in which two corners are cut off. Note that FIG. 19 is a diagram only for the purpose of illustrating cutouts in the first light emitting region 11R, the second light emitting region 11G, and the third light emitting region 11B, and illustrates the light emitting regions by ignoring a relationship between the sizes of the light emitting regions.

A color filter layer 51R, 51G, 51B may be formed on a surface side of the second substrate 42 facing the first substrate 41. In this case, the vertical arrangement of the color filter layers 51R, 51G, and 51B is upside down from the vertical arrangement of the color filter layers 51R, 51G, and 51B described in each of the embodiments. For example, in the first embodiment illustrated in FIG. 1, the blue color filter layer 51B has a reverse taper, and the green color filter layer 51G has a forward taper when viewed from a side of the first substrate. Even in such a case, the display device needs to satisfy the requirements in the display devices according to the first and second aspects of the present disclosure. The same applies to the display devices of the other embodiments.

In a boundary region between the adjacent color filter layers 51R, 51G, and 51B, a structure (transparent resin layer) constituted by a transparent resin may be disposed in a region of a bottom including a bottom surface of the color filter layer. In such a mode, a boundary line of a bottom surface of the color filter layer 51R, 51G, 51B facing the light emitting region 11R, 11G, 11B is located on the structure.

In the embodiments, the light emitting element driving unit is constituted by MOSFET, but can be also constituted by TFT. The first electrode and the second electrode may each have a single layer structure or a multilayer structure.

A light shielding layer may be disposed between a light emitting element and a light emitting element in order to prevent light emitted from a certain light emitting element from entering a light emitting element adjacent to the certain light emitting element to cause optical crosstalk. In other words, a groove may be formed between a light emitting element and a light emitting element, and the groove may be filled with a light shielding material to form the light shielding layer. By disposing the light shielding layer in this way, it is possible to reduce a ratio at which light emitted from a certain light emitting element enters an adjacent light emitting element, and to suppress occurrence of a phenomenon that color mixing occurs and chromaticity of the entire pixels is shifted from desired chromaticity. Specific examples of a light shielding material constituting the light shielding layer include a material capable of shielding light, such as titanium (Ti), chromium (Cr), tungsten (W), tantalum (Ta), aluminum (Al), or MoSi₂. The light shielding layer can be formed by a vapor deposition method including an electron beam vapor deposition method, a hot filament vapor deposition method, and a vacuum vapor deposition method, a sputtering method, a CVD method, an ion plating method, and the like.

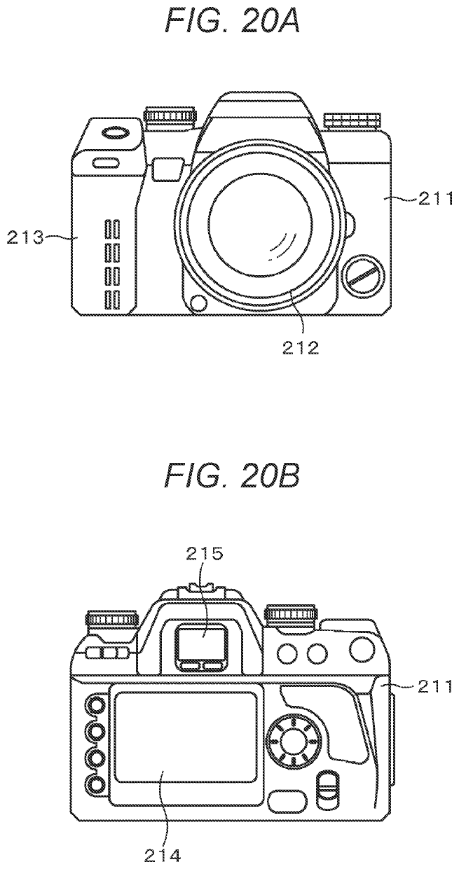

The display device of the present disclosure can be applied to a lens interchangeable single-lens reflex type digital still camera. FIG. 20A illustrates a front view of the digital still camera, and FIG. 20B illustrates a rear view thereof. This lens interchangeable single-lens reflex type digital still camera has, for example, an interchangeable imaging lens unit (interchangeable lens) 212 on the front right side of a camera body 211, and has a grip portion 213 to be gripped by an imaging person on the front left side thereof. In addition, a monitor 214 is disposed at substantially the center of a rear surface of the camera body 211. An electronic viewfinder (eyepiece window) 215 is disposed above a monitor 214. By looking through the electronic viewfinder 215, an imaging person can visually confirm an image of a subject guided from the imaging lens unit 212 and determine a composition. In the lens interchangeable single-lens reflex type digital still camera having such a configuration, the display device of the present disclosure can be used as the electronic viewfinder 215.

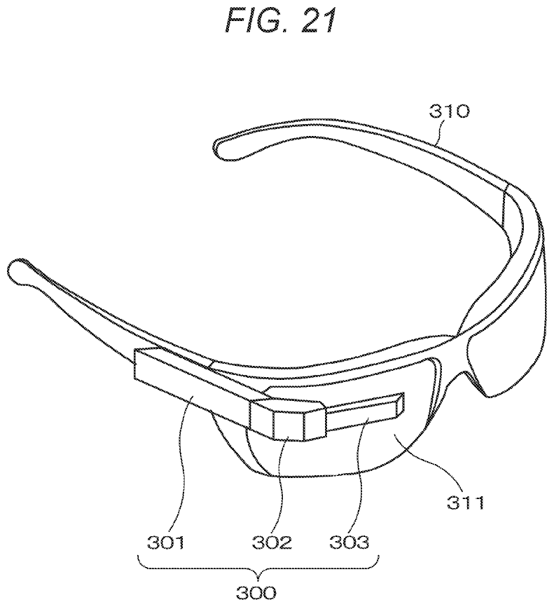

Alternatively, the display device of the present disclosure can be applied to a head mounted display. As FIG. 21 illustrates an external view, a head mounted display 300 is constituted by a transmissive head mounted display having a main body 301, an arm 302 and a lens barrel 303. The main body 301 is connected to the arm 302 and glasses 310. Specifically, an end of the main body 301 in a long side direction is attached to the arm 302. Furthermore, one of side surfaces of the main body 301 is connected to the glasses 310 via a connecting member (not illustrated). Note that the main body 301 may be directly mounted on the head of a human body. The main body 301 has a control substrate for controlling operation of the head mounted display 300 and a display unit built-in. The arm 302 supports the lens barrel 303 with respect to the main body 301 by connecting the main body 301 to the lens barrel 303. Specifically, the arm 302 fixes the lens barrel 303 to the main body 301 by being bonded to an end of the main body 301 and an end of the lens barrel 303. Furthermore, the arm 302 has a built-in signal line for communicating data related to an image provided from the main body 301 to the lens barrel 303. The lens barrel 303 projects image light provided from the main body 301 via the arm 302 toward the eyes of a user wearing the head mounted display 300 through the lens 311 of the glasses 310. In the head mounted display 300 having the configuration described above, the display device of the present disclosure can be used as the display unit built in the main body 301.

In a case where a resonator structure is disposed, a light reflecting layer 37 may be formed below the first electrode 31 (on a side of the first substrate 41). That is, in a case where the light reflecting layer 37 is disposed on the base body 26 and the first electrode 31 is disposed on an interlayer insulating layer 38 covering the light reflecting layer 37, it is only required to constitute each of the first electrode 31, the light reflecting layer 37, and the interlayer insulating layer 38 by the above-described materials. The light reflecting layer 37 may be connected to the contact hole (contact plug) 27, or does not have to be connected thereto.

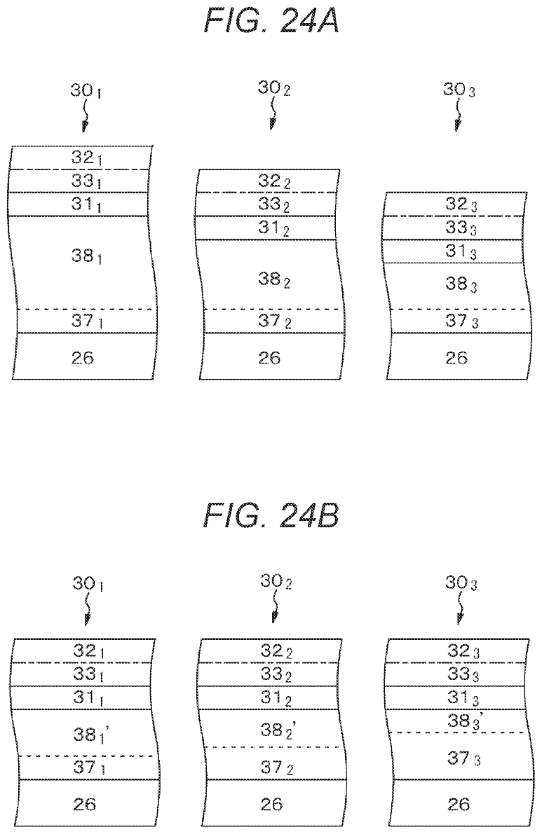

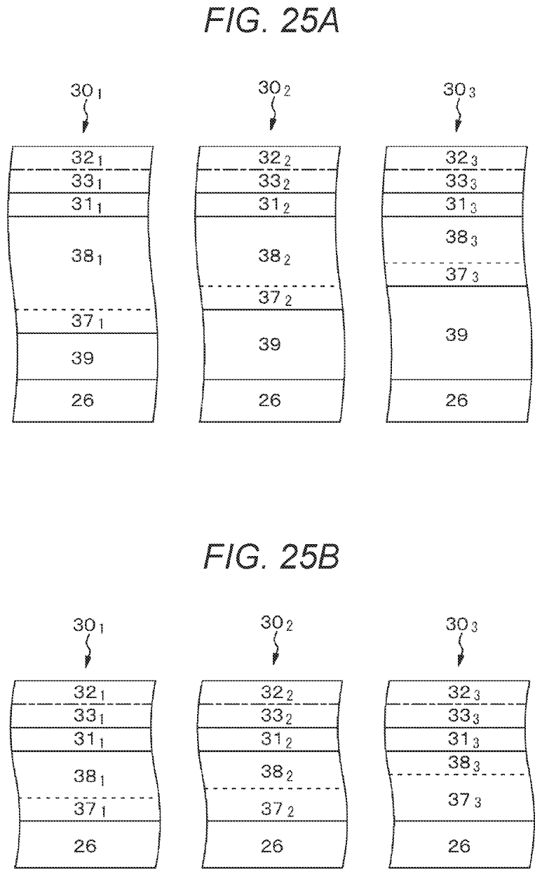

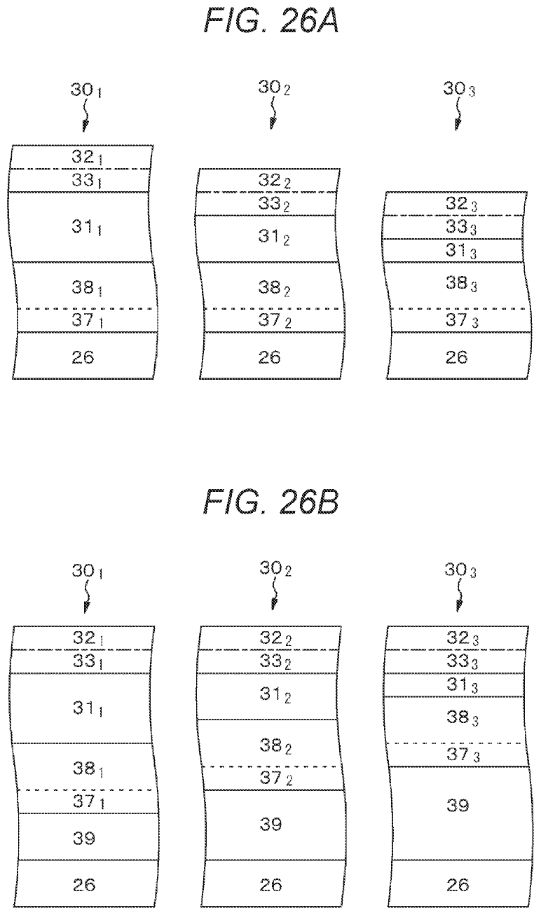

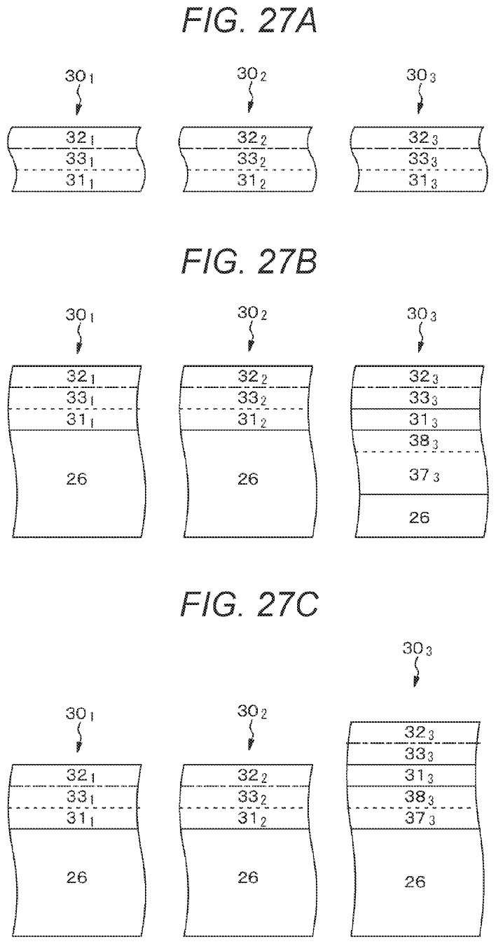

Hereinafter, the resonator structure will be described on the basis of first to eighth examples with reference to FIG. 24A (first example), FIG. 24B (second example), FIG. 25A (third example), FIG. 25B (fourth example), FIG. 26A (fifth example), FIG. 26B (sixth example), FIG. 27A (seventh example), and FIGS. 27B and 27C (eighth example). Here, in the first to fourth and seventh examples, the thickness of a first electrode is the same, and the thickness of a second electrode is the same in light emitting portions. Meanwhile, in the fifth and sixth examples, the thickness of the first electrode is different among the light emitting portions, and the thickness of the second electrode is the same in the light emitting portions. Furthermore, in the eighth example, the thickness of the first electrode may be different among the light emitting portions or may be the same in the light emitting portions, and the thickness of the second electrode is the same in the light emitting portions.

Note that in the following description, light emitting portions constituting a first light emitting element 10₁, a second light emitting element 10₂, and a third light emitting element 10₃ are represented by reference numerals 30₁, 30₂, and 30₃, respectively, the first electrode is represented by reference numeral 31₁, 31₂, 31₃, the second electrode is represented by reference numeral 32₁, 32₂, 32₃, an organic layer is represented by reference numeral 33₁, 33₂, 33₃, a light reflecting layer is represented by reference numeral 37₁, 37₂, 37₃, and an interlayer insulating layer is represented by reference numeral 38₁, 38₂, 38₃, 38_{1′}, 38₂′, 38₃′. In the following description, materials used are illustrative and can be changed appropriately.

In the illustrated examples, the resonator lengths of the first light emitting element 10₁, the second light emitting element 10₂, and the third light emitting element 10₃ derived from formulas (1-1) and (1-2) become shorter in order of the first light emitting element 10₁, the second light emitting element 10₂ and the third light emitting element 10₃. However, the present disclosure is not limited thereto, and it is only required to determine optimum resonator lengths by appropriately setting the values of m₁ and m₂.

A conceptual diagram of a light emitting element having the first example of the resonator structure is illustrated in FIG. 24A, a conceptual diagram of a light emitting element having the second example of the resonator structure is illustrated in FIG. 24B, a conceptual diagram of a light emitting element having the third example of the resonator structure is illustrated in FIG. 25A, and a conceptual diagram of a light emitting element having the fourth example of the resonator structure is illustrated in FIG. 25B. In some of the first to sixth and eighth examples, the interlayer insulating layer 38, 38′ is formed under the first electrode 31 of the light emitting portion 30, and the light reflecting layer 37 is formed under the interlayer insulating layer 38, 38′. In the first to fourth examples, the thickness of the interlayer insulating layer 38, 38′ is different among the light emitting portions 30₁, 30₂, and 30₃. In addition by appropriately setting the thickness of the interlayer insulating layer 38₁, 38₂, 38₃, 38₁′, 38₂′, 38₃′, it is possible to set an optical distance that causes optimum resonance with respect to an emission wavelength of the light emitting portion 30.

In the first example, the level of a first interface (indicated by dotted lines in the drawings) is the same in the light emitting portions 30₁, 30₂, and 30₃, while the level of a second interface (indicated by alternate long and short dash lines in the drawings) is different among the light emitting portions 30₁, 30₂, and 30₃. Furthermore, in the second example, the level of the first interface is different among the light emitting portions 30₁, 30₂, and 30₃, while the level of the second interface is the same in the light emitting portions 30₁, 30₂, and 30₃.

In the second example, the interlayer insulating layer 38₁′, 38₂′, 38₃′ is constituted by an oxide film in which a surface of the light reflecting layer 37 is oxidized. The interlayer insulating layer 38′ constituted by an oxide film is constituted by, for example, aluminum oxide, tantalum oxide, titanium oxide, magnesium oxide, zirconium oxide, and the like depending on a material constituting the light reflecting layer 37. Oxidation of the surface of the light reflecting layer 37 can be performed by, for example, the following method. That is, the first substrate 41 on which the light reflecting layer 37 is formed is immersed in an electrolytic solution filled in a container. Furthermore, a cathode is disposed so as to face the light reflecting layer 37. Then, the light reflecting layer 37 is anodized with the light reflecting layer 37 as an anode. The film thickness of the oxide film obtained by anodization is proportional to a potential difference between the light reflecting layer 37, which is an anode, and a cathode. Therefore, the light reflecting layers 37₁, 37₂, and 37₃ are anodized in a state where voltages corresponding to the light emitting portions 30₁, 30₂, and 30₃ are applied to the light reflecting layers 37₁, 37₂, and 37₃, respectively. This makes it possible to collectively form the interlayer insulating layers 38₁′, 38₂′, and 38₃′ constituted by oxide films having different thicknesses on a surface of the light reflecting layer 37. The thickness of the light reflecting layer 37₁, 37₂, 37₃ and the thickness of the interlayer insulating layer 38₁′, 38₂′, 38₃′ are different among the light emitting portions 30₁, 30₂, and 30₃.

In the third example, a base film 39 is disposed under the light reflecting layer 37, and the thickness of the base film 39 is different among the light emitting portions 30₁, 30₂, and 30₃. That is, in the illustrated example, the thickness of the base film 39 becomes thicker in order of the light emitting portion 30₁, the light emitting portion 30₂, and the light emitting portion 30₃.

In the fourth example, the thickness of the light reflecting layer 37₁, 37₂, 37₃ at the time of film formation is different among the light emitting portions 30₁, 30₂, and 30₃. In the third and fourth examples, the level of the second interface is the same in the light emitting portions 30₁, 30₂, and 30₃, while the level of the first interface is different among the light emitting portions 30₁, 30₂, and 30₃.

In the fifth and sixth examples, the thickness of the first electrode 31₁, 31₂, 31₃ is different among the light emitting portions 30₁, 30₂, and 30₃. The thickness of the light reflecting layer 37 is the same in the light emitting portions 30.

In the fifth example, the level of the first interface is the same in the light emitting portions 30₁, 30₂, and 30₃, while the level of the second interface is different among the light emitting portions 30₁, 30₂, and 30₃.

In the sixth example, the base film 39 is disposed under the light reflecting layer 37, and the thickness of the base film 39 is different among the light emitting portions 30₁, 30₂, and 30₃. That is, in the illustrated example, the thickness of the base film 39 becomes thicker in order of the light emitting portion 30₁, the light emitting portion 30₂, and the light emitting portion 30₃. In the sixth example, the level of the second interface is the same in the light emitting portions 30₁, 30₂, and 30₃, while the level of the first interface is different among the light emitting portions 30₁, 30₂, and 30₃.

In the seventh example, the first electrode 31₁, 31₂, 31₃ also serves as a light reflecting layer, and the optical constant (specifically, the phase shift amount) of a material constituting the first electrode 31₁, 31₂, 31₃ is different among the light emitting portions 30₁, 30₂, and 30₃. For example, it is only required to constitute the first electrode 31₁ of the light emitting portion 30₁ by copper (Cu), and it is only required to constitute the first electrode 31₂ of the light emitting portion 30₂ and the first electrode 31₃ of the light emitting portion 30₃ by aluminum (Al).

Furthermore, in the eighth example, the first electrode 31₁, 31₂ also serves as a light reflecting layer, and the optical constant (specifically, the phase shift amount) of a material constituting the first electrode 31₁, 31₂ is different among the light emitting portions 30₁ and 30₂. For example, it is only required to constitute the first electrode 31₁ of the light emitting portion 30₁ by copper (Cu), and it is only required to constitute the first electrode 31₂ of the light emitting portion 30₂ and the first electrode 31₃ of the light emitting portion 30₃ by aluminum (Al). In the eighth example, for example, the seventh example is applied to the light emitting portions 30₁ and 30₂, and the first example is applied to the light emitting portion 30₃. The thicknesses of the first electrodes 31₁, 31₂, and 31₃ may be different from or the same as each other.

Note that the present disclosure can have the following configurations.

### [A01] <<Display Device: First Aspect>>

A display device formed by arranging, on a base body, a plurality of light emitting element groups each including:

a first light emitting element including a first light emitting region and a first color filter layer disposed above the first light emitting region;

a second light emitting element including a second light emitting region and a second color filter layer disposed above the second light emitting region; and

a first light emitting element including a third light emitting region and a third color filter layer disposed above the third light emitting region, in which

in adjacent light emitting elements, an angle formed by the shortest line segment connecting a boundary line of a bottom surface of a color filter layer facing a light emitting region and an end of the light emitting region with a normal line of the base body is the same in the light emitting elements.

### [A02] <<Display Device: Second Aspect>>

A display device formed by arranging, on a base body, a plurality of light emitting element groups each including:

a first light emitting element including a first light emitting region and a first color filter layer disposed above the first light emitting region;

a second light emitting element including a second light emitting region and a second color filter layer disposed above the second light emitting region; and

a first light emitting element including a third light emitting region and a third color filter layer disposed above the third light emitting region, in which

in adjacent light emitting elements, a distance from an orthogonal projection image of a boundary line of a bottom surface of a color filter layer facing a light emitting region onto the base body to an orthogonal projection image of an end of the light emitting region onto the base body is the same in the light emitting elements.

[A03] The display device according to [A01] or [A02], in which the area of an orthogonal projection image of a top surface region of a color filter layer surrounded by a boundary line between a top surface of a color filter layer and a top surface of a color filter layer onto the base body is the same in the first light emitting element, the second light emitting element, and the third light emitting element.
[A04] The display device according to [A03], in which the area of a light emitting region is different among the first light emitting element, the second light emitting element, and the third light emitting element.
[A05] The display device according to [A01] or [A02], in which the area of an orthogonal projection image of a top surface region of a color filter layer surrounded by a boundary line between a top surface of a color filter layer and a top surface of a color filter layer onto the base body is different among the first light emitting element, the second light emitting element, and the third light emitting element.
[A06] The display device according to [A05], in which the area of a light emitting region is the same in the first light emitting element, the second light emitting element, and the third light emitting element.
[A07] The display device according to any one of [A01] to [A06], in which the first light emitting region, the second light emitting region, and the third light emitting region emit white light.
[A08] The display device according to any one of [A01] to [A06], in which the first light emitting region emits red light, the second light emitting region emits green light, and the third light emitting region emits blue light.
[A09] The display device according to any one of [A01] to [A08], in which

the first light emitting elements constituting the plurality of light emitting element groups are arranged in a first direction,

the second light emitting elements constituting the plurality of light emitting element groups are arranged in the first direction, and

the third light emitting elements constituting the plurality of light emitting element groups are arranged in the first direction.

[A10] The display device according to any one of [A01] to [A08], in which

the light emitting element group is constituted by four light emitting elements arranged in 2×2,

the first light emitting element is arranged adjacent to the two third light emitting elements,

the second light emitting element is arranged adjacent to the two third light emitting elements, and

each of the two third light emitting elements is arranged adjacent to the first light emitting element and the second light emitting element.

[A11] The display device according to any one of [A01] to [A08], in which,

the light emitting element group is constituted by the one first light emitting element, the one second light emitting element, and the one third light emitting element,

the first light emitting element is arranged adjacent to the second light emitting element and the third light emitting element, and

the second light emitting element is arranged adjacent to the first light emitting element and the third light emitting element.

### REFERENCE SIGNS LIST

10, 10R, 10G, 10B Light emitting element
11, 11R, 11G, 11B Light emitting region
11GR_{R}, 11R_{L}, 11G_{R}, 11G_{L}, 11B_{R}, 11B_{L} End of light emitting region
Transistor
21 Gate electrode
22 Gate insulating layer
23 Channel forming region
24 Source/drain region
25 Element isolating region
26 Base body
28 insulating layer
27 Contact plug
29 Opening
31 First electrode
32 Second electrode
33 Organic layer
34 Protective film
35 Resin layer (sealing resin layer)
37 Light reflecting layer
38 Interlayer insulating layer
39 Base film
41 First substrate
42 Second substrate
51R, 51G, 51B Color filter layer
52₁, 52₂, 52₃, 53₁, 53₂ Boundary line of color filter layer

1. A display device formed by arranging, on a base body, a plurality of light emitting element groups each including:
a first light emitting element including a first light emitting region and a first color filter layer disposed above the first light emitting region;
a second light emitting element including a second light emitting region and a second color filter layer disposed above the second light emitting region; and
a first light emitting element including a third light emitting region and a third color filter layer disposed above the third light emitting region, wherein
in adjacent light emitting elements, an angle formed by the shortest line segment connecting a boundary line of a bottom surface of a color filter layer facing a light emitting region and an end of the light emitting region with a normal line of the base body is the same in the light emitting elements.

2. The display device according to claim 1, wherein the area of an orthogonal projection image of a top surface region of a color filter layer surrounded by a boundary line between a top surface of a color filter layer and a top surface of a color filter layer onto the base body is the same in the first light emitting element, the second light emitting element, and the third light emitting element.

3. The display device according to claim 2, wherein the area of a light emitting region is different among the first light emitting element, the second light emitting element, and the third light emitting element.

4. The display device according to claim 1, wherein the area of an orthogonal projection image of a top surface region of a color filter layer surrounded by a boundary line between a top surface of a color filter layer and a top surface of a color filter layer onto the base body is different among the first light emitting element, the second light emitting element, and the third light emitting element.

5. The display device according to claim 4, wherein the area of a light emitting region is the same in the first light emitting element, the second light emitting element, and the third light emitting element.

6. The display device according to claim 1, wherein the first light emitting region, the second light emitting region, and the third light emitting region emit white light.

7. The display device according to claim 1, wherein the first light emitting region emits red light, the second light emitting region emits green light, and the third light emitting region emits blue light.

8. The display device according to claim 1, wherein
the first light emitting elements constituting the plurality of light emitting element groups are arranged in a first direction,
the second light emitting elements constituting the plurality of light emitting element groups are arranged in the first direction, and
the third light emitting elements constituting the plurality of light emitting element groups are arranged in the first direction.

9. The display device according to claim 1, wherein
the light emitting element group is constituted by four light emitting elements arranged in 2×2,
the first light emitting element is arranged adjacent to the two third light emitting elements,
the second light emitting element is arranged adjacent to the two third light emitting elements, and
each of the two third light emitting elements is arranged adjacent to the first light emitting element and the second light emitting element.

10. The display device according to claim 1, wherein
the light emitting element group is constituted by the one first light emitting element, the one second light emitting element, and the one third light emitting element,
the first light emitting element is arranged adjacent to the second light emitting element and the third light emitting element, and
the second light emitting element is arranged adjacent to the first light emitting element and the third light emitting element.

11. A display device formed by arranging, on a base body, a plurality of light emitting element groups each including:
a first light emitting element including a first light emitting region and a first color filter layer disposed above the first light emitting region;
a second light emitting element including a second light emitting region and a second color filter layer disposed above the second light emitting region; and
a first light emitting element including a third light emitting region and a third color filter layer disposed above the third light emitting region, wherein
in adjacent light emitting elements, a distance from an orthogonal projection image of a boundary line of a bottom surface of a color filter layer facing a light emitting region onto the base body to an orthogonal projection image of an end of the light emitting region onto the base body is the same in the light emitting elements.

12. The display device according to claim 11, wherein the area of an orthogonal projection image of a top surface region of a color filter layer surrounded by a boundary line between a top surface of a color filter layer and a top surface of a color filter layer onto the base body is the same in the first light emitting element, the second light emitting element, and the third light emitting element.

13. The display device according to claim 12, wherein the area of a light emitting region is different among the first light emitting element, the second light emitting element, and the third light emitting element.

14. The display device according to claim 11, wherein the area of an orthogonal projection image of a top surface region of a color filter layer surrounded by a boundary line between a top surface of a color filter layer and a top surface of a color filter layer onto the base body is different among the first light emitting element, the second light emitting element, and the third light emitting element.

15. The display device according to claim 14, wherein the area of a light emitting region is the same in the first light emitting element, the second light emitting element, and the third light emitting element.

16. The display device according to claim 11, wherein the first light emitting region, the second light emitting region, and the third light emitting region emit white light.

17. The display device according to claim 11, wherein the first light emitting region emits red light, the second light emitting region emits green light, and the third light emitting region emits blue light.

18. The display device according to claim 11, wherein
the first light emitting elements constituting the plurality of light emitting element groups are arranged in a first direction,
the second light emitting elements constituting the plurality of light emitting element groups are arranged in the first direction, and
the third light emitting elements constituting the plurality of light emitting element groups are arranged in the first direction.

19. The display device according to claim 11, wherein
the light emitting element group is constituted by four light emitting elements arranged in 2×2,
the first light emitting element is arranged adjacent to the two third light emitting elements,
the second light emitting element is arranged adjacent to the two third light emitting elements, and
each of the two third light emitting elements is arranged adjacent to the first light emitting element and the second light emitting element.

20. The display device according to claim 11, wherein
the light emitting element group is constituted by the one first light emitting element, the one second light emitting element, and the one third light emitting element,
the first light emitting element is arranged adjacent to the second light emitting element and the third light emitting element, and
the second light emitting element is arranged adjacent to the first light emitting element and the third light emitting element.
